(19) United States
(12) Patent Application Publication
(10) Pub. No.: US 2026/0231801 A1
(43) Pub. Date: Aug. 6, 2026

(54) SEMICONDUCTOR STRUCTURE AND METHOD FOR MANUFACTURING SAME

(71) Applicant: MITSUI CHEMICALS, INC., Chuo-ku, Tokyo (JP)

(72) Inventors: Yasuhisa KAYABA, Chuo-ku, Tokyo (JP); Satoshi INADA, Chuo-ku, Tokyo (JP); Kahori TAMURA, Chuo-ku, Tokyo (JP)

(73) Assignee: MITSUI CHEMICALS, INC., Chuo-ku, Tokyo (JP)

(21) Appl. No.: 19/152,613

(22) PCT Filed: Feb. 1, 2024
(86) PCT No.: PCT/JP2024/003351

§ 371 Date: Jul. 31, 2025

(30) Foreign Application Priority Data
Feb. 3, 2023 (JP) 2023-015651

(51) Int. Cl. H10W 70/695; H10W 70/08; H10W 70/60; H10W 70/63; H10W 72/00; H10W 74/10; H10W 80/00; H10W 90/00; H10W 90/10

(52) U.S. Cl. CPC H10W 70/695; H10W 70/08; H10W 70/618; H10W 70/63; H10W 72/823; H10W 74/117; H10W 80/312; H10W 80/327; H10W 90/10; H10W 90/7295; H10W 90/794

(57) ABSTRACT

Provided is a semiconductor structure including: an organic bonding layer that includes an organic insulating layer and a metal pad; plural silicon dies that are arranged in a two-dimensional manner on the organic bonding layer and hybrid-bonded thereto; and a resin mold layer that is filled between the plural silicon dies on the organic bonding layer.

### TECHNICAL FIELD

The present disclosure relates to a semiconductor structure and a method of manufacturing the same.

### BACKGROUND ART

In recent years, in the field of semiconductor devices, a technology of bonding a semiconductor chip (e.g., a silicon die) onto a redistribution layer has been considered (see, for example, Non-Patent Document 1).
Non-Patent Document 1: Website of SHINKO ELECTRIC INDUSTRIES CO., LTD., “Product,” “Semiconductor Package.” “Substrate” (for semiconductor packages), “2.3D Package Substrate~i-THOP (registered trademark)~(under development),” [online], SHINKO ELECTRIC INDUSTRIES CO., LTD. [Searched on Jan. 27, 2023], Internet <URL: https://wiww.shinko.co.jp/product/package/substrate/i-thop.php>

### SUMMARY OF INVENTION

### Technical Problem

The attachment of a semiconductor chip (e.g., a silicon die) onto the redistribution layer is typically accomplished by a solder and an epoxy adhesive.

In this case, however, there is room for improvement in terms of narrowing of the wiring pitch.

The disclosure has been made in view of the above-described problem.

An object of one aspect of the disclosure is to provide a semiconductor structure that allows for a narrowing of the wiring pitch and a method of manufacturing the same.

### Solution to Problem

Specific means for solving the above-described problem include the following aspects.
<1> A semiconductor structure, including:
an organic bonding layer that includes an organic insulating layer and a metal pad;
a plurality of silicon dies that are arranged in a two-dimensional manner on the organic bonding layer and hybrid-bonded to the organic bonding layer; and
a resin mold layer that is filled between the plurality of silicon dies on the organic bonding layer.
<2> The semiconductor structure according to <1>, further including a redistribution layer that is arranged at a side opposite to a side at which the plurality of silicon dies are arranged as viewed from the organic bonding layer.
<3> The semiconductor structure according to <1>, further including a build-up substrate that is arranged at a side opposite to a side at which the plurality of silicon dies are arranged as viewed from the organic bonding layer.
<4> The semiconductor structure according to <1>, further including:
a high-density wiring layer that is arranged at a side opposite to a side at which the plurality of silicon dies are arranged as viewed from the organic bonding layer; and
a build-up substrate that is arranged at a side opposite to a side at which the organic bonding layer is arranged as viewed from the high-density wiring layer.
<5> The semiconductor structure according to any one of <1> to <4>,
wherein the organic insulating layer includes a cured product of the following composition A or a cured product of the following composition B,
wherein the composition A is a composition containing:
a compound (A) having an Si—O bond and a cationic functional group containing at least one selected from a primary nitrogen atom or a secondary nitrogen atom;
a compound (B) having three or more —C(═O)OX groups (wherein X is a hydrogen atom or an alkyl group having from 1 to 6 carbon atoms), and among the three or more —C(═O)OX groups, one to six are —C(═O)OH groups; and
a compound (C) having a ring structure and one or more primary nitrogen atoms directly bonded to the ring structure,
the composition A having a ratio of the primary nitrogen atom and secondary nitrogen atom contained in the compound (A) to a total of the primary nitrogen atom and secondary nitrogen atom contained in the compound (A) and the primary nitrogen atoms contained in the compound (C) of from 3% by mole to 95% by mole, and
wherein the composition B is a composition containing at least one of a compound (X1) having a structure represented by the following Formula (1) and a molecular weight of from 400 to 5000 or a compound (X2) having a structure represented by the following Formula (2) and a molecular weight of from 400 to 5000:

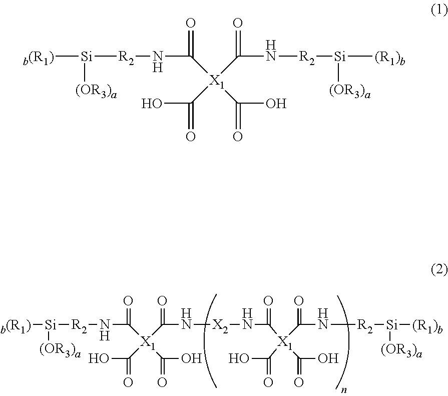

wherein in Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride;
in Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.
<6> The semiconductor structure according to any one of <1> to <5>, wherein
each of the plurality of silicon dies includes a silicon die body and a silicon die bonding layer that is in contact with the organic bonding layer, and
the silicon die bonding layer includes a metal pad and any one of an organic insulating layer, an SiO₂ layer, an SiCN layer or an SiN layer.
<7> The semiconductor structure according to any one of <1> to <6>, wherein the resin mold layer covers upper surfaces of the plurality of silicon dies.
<8> The semiconductor structure according to any one of <1> to <7>, further including a second organic bonding layer that includes an organic insulating layer and a metal pad, and that is arranged at a side opposite to a side at which the organic bonding layer is arranged as viewed from the plurality of silicon dies.
<9> The semiconductor structure according to <8>, further including a plurality of second silicon dies that are arranged in a two-dimensional manner on the second organic bonding layer and hybrid-bonded to the second organic bonding layer.
<10> The semiconductor structure according to <9>, wherein
each of the plurality of second silicon dies includes a silicon die body and a silicon die bonding layer that is in contact with the second organic bonding layer, and
the silicon die bonding layer includes a metal pad and any one of an organic insulating layer, an SiO₂ layer, an SiCN layer or an SiN layer.
<11> The semiconductor structure according to any one of <8> to <10>, further including a second redistribution layer that is arranged between the second organic bonding layer and the plurality of silicon dies.
<12> The semiconductor structure according to any one of <8> to <11>, further including a temporary fixing substrate or build-up substrate, which is arranged at a side opposite to a side at which the plurality of silicon dies are arranged as viewed from the organic bonding layer.
<13> A method of manufacturing a semiconductor structure, including:
a step of forming a redistribution layer on a temporary fixing substrate;
a step of forming an organic bonding layer, which includes an organic insulating layer and a metal pad, on the redistribution layer that is temporarily fixed on the temporary fixing substrate;
a step of arranging a plurality of silicon dies in a two-dimensional manner on the organic bonding layer formed on the redistribution layer and hybrid-bonding the silicon dies to the organic bonding layer;
a step of forming a resin mold layer that is filled between the plurality of silicon dies on the organic bonding layer and covers upper surfaces of the plurality of silicon dies; and
a step of removing the temporary fixing substrate.
<14> A method of manufacturing a semiconductor structure, including:
a step of forming a redistribution layer on a temporary fixing substrate;
a step of forming an organic bonding layer, which includes an organic insulating layer and a metal pad on the redistribution layer that is temporarily fixed on the temporary fixing substrate;
a step of arranging a plurality of silicon dies in a two-dimensional manner on the organic bonding layer formed on the redistribution layer and hybrid-bonding the silicon dies to the organic bonding layer;
a step of forming a resin mold layer that is filled between the plurality of silicon dies on the organic bonding layer and that covers upper surfaces of the plurality of silicon dies;
a step of removing the temporary fixing substrate;
a step of forming an electrode at a side at which the temporary fixing substrate of the redistribution layer is removed; and
a step of bonding the redistribution layer and a build-up substrate via the electrode.
<15> A method of manufacturing a semiconductor structure, including:
a step of forming an organic bonding layer, which includes an organic insulating layer and a metal pad on a temporary fixing substrate;
a step of arranging a plurality of silicon dies in a two-dimensional manner on the organic bonding layer formed on the temporary fixing substrate and hybrid-bonding the silicon dies to the organic bonding layer;
a step of forming a resin mold layer that is filled between the plurality of silicon dies on the organic bonding layer and that covers upper surfaces of the plurality of silicon dies; and
a step of removing the temporary fixing substrate.
<16> A method of manufacturing a semiconductor structure, including:
a step of forming an organic bonding layer, which includes an organic insulating layer and a metal pad on a temporary fixing substrate;
a step of arranging a plurality of silicon dies in a two-dimensional manner on the organic bonding layer formed on the temporary fixing substrate and hybrid-bonding the silicon dies to the organic bonding layer;
a step of forming a resin mold layer that is filled between the plurality of silicon dies on the organic bonding layer and that covers upper surfaces of the plurality of silicon dies: a step of removing the temporary fixing substrate;
a step of forming an electrode at a side at which the temporary fixing substrate of the organic bonding layer is removed; and
a step of bonding the organic bonding layer and a build-up substrate via the electrode.
<17> A method of manufacturing a semiconductor structure, including:
a step of forming a high-density wiring layer on a build-up substrate:
a step of forming an organic bonding layer, which includes an organic insulating layer and a metal pad on the high-density wiring layer;
a step of arranging a plurality of silicon dies in a two-dimensional manner on the organic bonding layer formed on the high-density wiring layer and hybrid-bonding the silicon dies to the organic bonding layer; and
a step of forming a resin mold layer that is filled between the plurality of silicon dies on the organic bonding layer and covers upper surfaces of the plurality of silicon dies.
<18> The method of manufacturing a semiconductor structure according to any one of <13> to <17>, further including:
a step of removing a portion of the resin mold layer that covers the upper surfaces of the plurality of silicon dies so as to expose the upper surfaces of the plurality of silicon dies; and
a step of forming a second organic bonding layer, which includes an organic insulating layer and a metal pad on the plurality of silicon dies having the upper surfaces exposed and the resin mold layer.
<19> The method of manufacturing a semiconductor structure according to <18>, further including a step of arranging a plurality of second silicon dies in a two-dimensional manner on the second organic bonding layer and hybrid-bonding the second silicon dies to the second organic bonding layer.
<20> The method of manufacturing a semiconductor structure according to any one of <13> to <17>, further including:
a step of removing a portion of the resin mold layer that covers the upper surfaces of the plurality of silicon dies so as to expose the upper surfaces of the plurality of silicon dies; and
a step of forming a second redistribution layer on the plurality of silicon dies having the upper surfaces exposed and the resin mold layer; and
a step of forming a second organic bonding layer, which includes an organic insulating layer and a metal pad on the second redistribution layer.
<21> The method of manufacturing a semiconductor structure according to <20>, further including
a step of arranging a plurality of second silicon dies in a two-dimensional manner on the second organic bonding layer and hybrid-bonding the second silicon dies to the second organic bonding layer.
<22> The method of manufacturing a semiconductor structure according to any one of <13> to <21>,
wherein the step of forming an organic bonding layer includes curing the following composition A or the following composition B so as to form the organic insulating layer, wherein the composition A is a composition containing:
a compound (A) having an Si—O bond and a cationic functional group containing at least one selected from a primary nitrogen atom or a secondary nitrogen atom:
a compound (B) having three or more —C(═O)OX groups, wherein X is a hydrogen atom or an alkyl group having from 1 to 6 carbon atoms, and among the three or more —C(═O)OX groups, one to six are —C(═O)OH groups; and
a compound (C) having a ring structure and one or more primary nitrogen atoms directly bonded to the ring structure,
the composition A having a ratio of the primary nitrogen atom and secondary nitrogen atom contained in the compound (A) to a total of the primary nitrogen atom and secondary nitrogen atom contained in the compound (A) and the primary nitrogen atoms contained in the compound (C) of from 3% by mole to 95% by mole, and
wherein the composition B is a composition including at least one of a compound (X1) having a structure represented by the following Formula (1) and a molecular weight of from 400 to 5000 or a compound (X2) having a structure represented by the following Formula (2) and a molecular weight of from 400 to 5000:

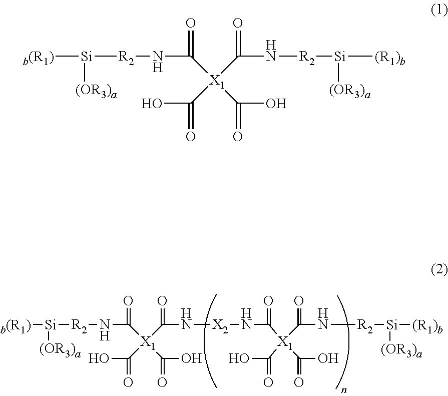

wherein, in Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride; and
wherein, in Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.

### Advantageous Effects of Invention

According to one aspect of the disclosure, a semiconductor structure that allows for the narrowing of the wiring pitch and a method of manufacturing the same are provided.

### BRIEF DESCRIPTION OF DRAWINGS

FIG. 1 is a schematic cross-sectional view of a first specific example of the semiconductor structure of the disclosure.

FIG. 2 is a schematic cross-sectional view of an example of an electronic device using the first specific example of the semiconductor structure of the disclosure.

FIG. 3A is a schematic flow diagram illustrating a step of manufacturing another example of an electronic device using the first specific example of the semiconductor structure of the disclosure.

FIG. 3B is a schematic flow diagram illustrating a step of manufacturing another example of an electronic device using the first specific example of the semiconductor structure of the disclosure.

FIG. 3C is a schematic flow diagram illustrating a step of manufacturing another example of an electronic device using the first specific example of the semiconductor structure of the disclosure.

FIG. 4 is a schematic cross-sectional view of a second specific example of the semiconductor structure of the disclosure.

FIG. 5A is a schematic flow diagram illustrating a step of manufacturing an example of an electronic device using the second specific example of the semiconductor structure of the disclosure.

FIG. 5B is a schematic flow diagram illustrating a step of manufacturing an example of an electronic device using the second specific example of the semiconductor structure of the disclosure.

FIG. 6 is a schematic cross-sectional view of a third specific example of the semiconductor structure of the disclosure.

FIG. 7A is a schematic flow diagram illustrating a step of manufacturing the first specific example of the semiconductor structure of the disclosure.

FIG. 7B is a schematic flow diagram illustrating a step of manufacturing the first specific example of the semiconductor structure of the disclosure.

FIG. 7C is a schematic flow diagram illustrating a step of manufacturing the first specific example of the semiconductor structure of the disclosure.

FIG. 7D is a schematic flow diagram illustrating a step of manufacturing the first specific example of the semiconductor structure of the disclosure.

FIG. 7E is a schematic flow diagram illustrating a step of manufacturing the first specific example of the semiconductor structure of the disclosure.

FIG. 8A is a schematic flow diagram illustrating a step of manufacturing the second specific example of the semiconductor structure of the disclosure.

FIG. 8B is a schematic flow diagram illustrating a step of manufacturing the second specific example of the semiconductor structure of the disclosure.

FIG. 8C is a schematic flow diagram illustrating a step of manufacturing the second specific example of the semiconductor structure of the disclosure.

FIG. 8D is a schematic flow diagram illustrating a step of manufacturing the second specific example of the semiconductor structure of the disclosure.

FIG. 9A is a schematic flow diagram illustrating a step of manufacturing the third specific example of the semiconductor structure of the disclosure.

FIG. 9B is a schematic flow diagram illustrating a step of manufacturing the third specific example of the semiconductor structure of the disclosure.

FIG. 9C is a schematic flow diagram illustrating a step of manufacturing the third specific example of the semiconductor structure of the disclosure.

FIG. 9D is a schematic flow diagram illustrating a step of manufacturing the third specific example of the semiconductor structure of the disclosure.

FIG. 10A is a schematic flow diagram illustrating a step of manufacturing a fourth specific example of the semiconductor structure of the disclosure.

FIG. 10B is a schematic flow diagram illustrating a step of manufacturing the fourth specific example of the semiconductor structure of the disclosure.

FIG. 10C is a schematic flow diagram illustrating a step of manufacturing the fourth specific example of the semiconductor structure of the disclosure.

FIG. 10D is a schematic flow diagram illustrating a step of manufacturing the fourth specific example of the semiconductor structure of the disclosure.

FIG. 11A is a schematic flow diagram illustrating a step of manufacturing a fifth specific example of the semiconductor structure of the disclosure.

FIG. 11B is a schematic flow diagram illustrating a step of manufacturing the fifth specific example of the semiconductor structure of the disclosure.

FIG. 11C is a schematic flow diagram illustrating a step of manufacturing the fifth specific example of the semiconductor structure of the disclosure.

FIG. 11D is a schematic flow diagram illustrating a step of manufacturing the fifth specific example of the semiconductor structure of the disclosure.

### DESCRIPTION OF EMBODIMENTS

In the disclosure, a numerical range expressed using “to” means a range that includes the numerical values before and after “to” as the lower and upper limits.

In the disclosure, in which numerical ranges are described in stages, the upper or lower limit value described in one numerical range may be replaced with the upper or lower limit value of another numerical range described in stages. In addition, in the numerical ranges described in the disclosure, the upper or lower limit of the numerical ranges may be replaced with values shown in the examples.

### [Semiconductor Structure]

The semiconductor structure of the disclosure may include:
an organic bonding layer that includes an organic insulating layer and a metal pad;
a plurality of silicon dies that are arranged in a two-dimensional manner on the organic bonding layer and hybrid-bonded to the organic bonding layer; and
a resin mold layer that is filled between the plurality of silicon dies on the organic bonding layer.

The semiconductor structure of the disclosure may include other elements (e.g., other layers and/or other materials).

In the semiconductor structure of the disclosure, silicon dies are hybrid-bonded onto an organic bonding layer, allowing for the narrowing of the wiring pitch, compared to a case in which the bonding of a semiconductor chip (e.g., silicon die) onto a redistribution layer or a bonding layer is carried out using a solder and an epoxy resin.

Furthermore, the organic bonding layer in the semiconductor structure of the disclosure includes an organic insulating layer that can be formed by a wet process such as a coating method. Therefore, the process of forming a bonding layer in the semiconductor structure of the disclosure is simpler than a case in which an inorganic bonding layer including an inorganic insulating layer such as SiO₂ is formed by a dry process, and the semiconductor structure of the disclosure is adaptable to semiconductor structures of various sizes.

The semiconductor structure of the disclosure may include a redistribution layer that is arranged at a side opposite to a side at which the plurality of silicon dies are arranged as viewed from the organic bonding layer.

An aspect of the semiconductor structure including a redistribution layer is a first specific example described below.

An aspect of the semiconductor structure not including a redistribution layer is a second specific example described below.

The semiconductor structure of the disclosure may include a build-up substrate that is arranged at a side opposite to a side at which the plurality of silicon dies are arranged as viewed from the organic bonding layer.

An aspect of the semiconductor structure including a build-up substrate may be an electronic device formed by bonding a build-up substrate to the semiconductor structure according to the first or second specific example (these details will be described below).

The semiconductor structure of the disclosure may include: a high-density wiring layer that is arranged at a side opposite to a side at which the plurality of silicon dies are arranged as viewed from the organic bonding layer; and a build-up substrate that is arranged at a side opposite to a side at which the organic bonding layer is arranged as viewed from the high-density wiring layer.

An aspect of the semiconductor structure including a high-density wiring layer and a build-up substrate is a third specific example described below.

In the semiconductor structure of the disclosure, the organic insulating layer may contain a cured product of the following composition A or a cured product of the following composition B.

The composition A is a composition containing:
a compound (A) having an Si—O bond and a cationic functional group containing at least one selected from a primary nitrogen atom or a secondary nitrogen atom: a compound (B) having three or more —C(═O)OX groups (wherein X is a hydrogen atom or an alkyl group having from 1 to 6 carbon atoms), and among the three or more —C(═O)OX groups, one to six are —C(═O)OH groups; and
a compound (C) having a ring structure and one or more primary nitrogen atoms directly bonded to the ring structure,
the composition A having a ratio of the primary nitrogen atom and secondary nitrogen atom contained in the compound (A) to a total of the primary nitrogen atom and secondary nitrogen atom contained in the compound (A) and the primary nitrogen atoms contained in the compound (C) of from 3% by mole to 95% by mole, and
the composition B is a composition
containing at least one of a compound (X1) having a structure represented by the following Formula (1) and a molecular weight of from 400 to 5,000 or a compound (X2) having a structure represented by the following Formula (2) and a molecular weight of from 400 to 5,000.

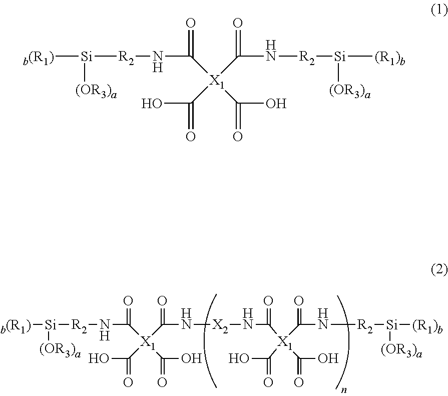

In Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride.

In Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.

The compositions A and B will be described in detail below.

In the semiconductor structure of the disclosure, each of the plurality of silicon dies may include a silicon die body and a silicon die bonding layer that is in contact with the organic bonding layer.

The silicon die bonding layer may include an organic insulating layer, an SiO₂ layer, an SiCN layer, or an SiN layer, and a metal pad.

In the semiconductor structure of the disclosure, the resin mold layer may cover upper surfaces of the plurality of silicon dies (e.g., the first and second specific examples described below).

The semiconductor structure of the disclosure may further include a second organic bonding layer including an organic insulating layer and a metal pad, which is arranged at a side opposite to a side at which the organic bonding layer is arranged as viewed from the plurality of silicon dies (e.g., the fourth and fifth specific examples described below).

The semiconductor structure of the disclosure, which includes the second organic bonding layer, may further include
a plurality of second silicon dies that are arranged in a two-dimensional manner on the second organic bonding layer and hybrid-bonded thereto (e.g., the fourth and fifth specific examples described below).

Each of the plurality of second silicon dies may include a silicon die body and a silicon die bonding layer that is in contact with the second organic bonding layer.

The silicon die bonding layer may include an organic insulating layer, an SiO₂ layer, an SiCN layer, or an SiN layer, and a metal pad.

The semiconductor structure of the disclosure, which includes the second organic bonding layer, may further include a second redistribution layer that is arranged between the second organic bonding layer and the plurality of silicon dies (e.g., the fourth and fifth specific examples described below).

The semiconductor structure of the disclosure, which includes the second organic bonding layer, may further include a temporary fixing substrate or build-up substrate that is arranged at a side opposite to a side at which the plurality of silicon dies are arranged as viewed from the organic bonding layer (e.g., the fourth and fifth specific examples described below).

Hereinafter, specific examples of the semiconductor structure of the disclosure will be described with reference to the drawings, if appropriate.

However, the semiconductor structure of the disclosure is not limited to the following specific examples.

In the following description, substantially identical elements (e.g., parts or portions) are denoted by the same reference numerals, and duplicate descriptions may be omitted.

### First Specific Example

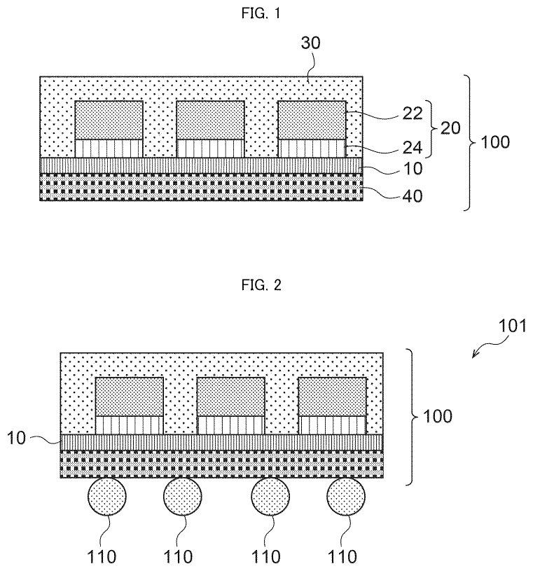

FIG. 1 is a schematic cross-sectional view of a semiconductor structure 100 as the first specific example of the semiconductor structure of the disclosure.

As shown in FIG. 1, the semiconductor structure 100 includes:
an organic bonding layer 10 that includes an organic insulating layer (not shown) and a metal pad (not shown);
a plurality of silicon dies 20 that are arranged in a two-dimensional manner on the organic bonding layer 10 and hybrid-bonded to the organic bonding layer 10;
a resin mold layer 30 that is filled between the plurality of silicon dies 20 on the organic bonding layer 10 and covers upper surfaces of the plurality of silicon dies 20; and
a redistribution layer 40 that is arranged at a side opposite to a side at which the plurality of silicon dies 20 are arranged as viewed from the organic bonding layer 10.

Each of the plurality of silicon dies 20 in the semiconductor structure 100 may include a silicon die body 22 and a silicon die bonding layer 24 that is in contact with the organic bonding layer 10.

The silicon die bonding layer 24 is not shown, but includes an organic insulating layer or SiO₂ layer and a metal pad.

In the semiconductor structure 100, the silicon dies 20 are hybrid-bonded onto the organic bonding layer 10, allowing for the narrowing of the wiring pitch, compared to a case in which the bonding of a semiconductor chip (e.g., silicon die) onto a redistribution layer or a bonding layer is carried out using a solder and an epoxy resin.

Next, preferred aspects of the elements of the semiconductor structure of the disclosure will be described.

### (Redistribution Layer)

As the redistribution layer (e.g., redistribution layer 40) in the disclosure, a known redistribution layer (RDL) consisting of a resin insulating material such as polyimide and Cu wiring can be used.

Examples of a method of forming a redistribution layer include:
a damascene process in which a resin insulating material is dry etched to form Cu wiring, and then planarized by CMP or the like, and
a method using semi-additive process-based Cu wiring formation and a photosensitive resin.

The configuration of a high-density wiring layer (e.g., a high-density wiring layer 42 in the third specific example described below) is the same as that of the redistribution layer.

### (Organic Bonding Layer)

The organic bonding layer in the disclosure (e.g., the above-described organic bonding layer 10) includes an organic insulating layer and a metal pad.

The organic insulating layer in the organic bonding layer is, for example, an insulating resin layer formed by a coating method.

Examples of materials for the organic insulating layer include polyimide, benzocyclobutene resin (BCB), polymaleimide, siloxaneimide, epoxy-modified siloxane, polybenzoxazole, and sol-gel silica. In particular, insulating materials containing siloxane are preferred because they can be bonded at room temperature.

As described above, the organic insulating layer preferably contains a cured product of the composition A or a cured product of the composition B.

The organic insulating layer preferably has a curing reaction rate of 70% or more.

The metal pad in the organic bonding layer is a pad that includes a metal such as Cu, gold, or tin. Examples of a method of forming a metal pad include:
a method of forming a metal pad using a damascene process after forming an organic insulating layer;
a method of forming holes by laser drilling after forming an organic insulating layer, followed by forming a metal pad by performing plating or sputtering, and
a method of forming a metal pad by a semi-additive process, followed by forming an organic insulating layer is formed and then forming an organic bonding layer by CMP or diamond bit cutting.

At the bonding surface of the organic bonding layer, the metal pad may be recessed or protruded with respect to the organic insulating layer.

### (Silicon Die)

The silicon die (e.g., the above-described silicon die 20) in the disclosure includes a silicon die body (e.g., a silicon die body 22) and a silicon die bonding layer formed on a surface of the silicon die body (e.g., a silicon die bonding layer 24).

The silicon die body itself is a silicon substrate that contains a device layer such as a memory or logic circuit.

The silicon die bonding layer may include an organic insulating layer, an SiO₂ layer, an SiCN layer, or an SiN layer, and a metal pad.

Preferred aspects of the organic insulating layer in the silicon die bonding layer are the same as preferred aspects of the organic insulating layer in the organic bonding layer described above.

The SiO₂ layer, SiCN layer, or SiN layer in the silicon die bonding layer can be formed by a known gas phase method.

Preferred aspects of the metal pad in the silicon die bonding layer are the same as preferred aspects of the metal pad in the organic bonding layer described above.

### (Hybrid Bonding)

In the semiconductor structure in the disclosure, a silicon die (e.g., the above-described silicon die 20) is hybrid-bonded onto an organic bonding layer (e.g., the above-described organic bonding layer 10).

The hybrid bonding can be carried out in an arrangement that the organic bonding layer and the silicon die bonding layer in the silicon die are in contact with each other.

In the disclosure, hybrid bonding refers to a type of bonding in which two surfaces on which an electrode and an insulating material are exposed are brought into contact with each other, thereby bonding electrodes to each other and insulating films to each other.

Examples of hybrid bonding of the organic bonding layer and the silicon die include; thermal compression bonding, and
a method in which insulating layers are bonded together at room temperature, and then metal pads are bonded together by heating or gang bonding.

From the viewpoint of increasing the bonding strength, it is preferable to perform a surface activation treatment (such as ozone treatment, plasma treatment, or fast atom beam treatment) on the bonding surface of the silicon die and the bonding surface of the organic bonding layer before bonding.

In addition, from the viewpoint of promoting bonding between metal pads, it is preferable to remove the metal oxide film by cleaning the bonding surface with an acid such as citric acid before bonding.

### (Resin Mold Layer)

In the disclosure, an example of the material for the resin mold layer (e.g., the resin mold layer 30) is an epoxy resin.

### (Example of Type of Usage of Semiconductor Structure 100 According to First Specific Example)

Next, examples of the type of usage of a semiconductor structure 100 according to the first specific example will be described.

The semiconductor structure 100 is connected to a build-up substrate directly or via another member for use.

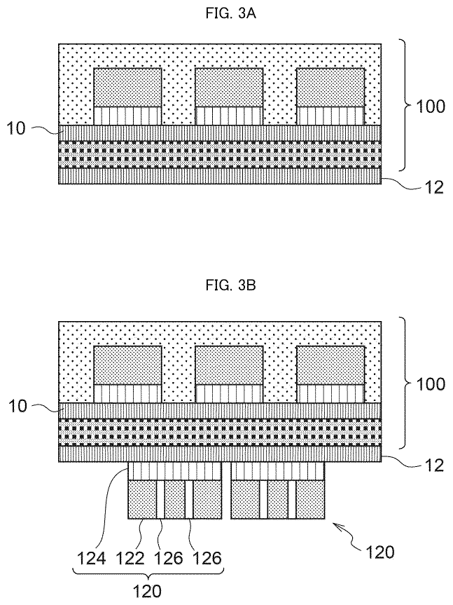

FIG. 2 is a schematic cross-sectional view of an example of an electronic device (electronic device 101) using a semiconductor structure 100 as the first specific example of the semiconductor structure of the disclosure.

As shown in FIG. 2, an electronic device 101 is obtained by connecting solder balls 110 to a surface of a semiconductor structure 100 opposite to a surface on which an organic bonding layer 10 is present as viewed from a redistribution layer 40 in a semiconductor structure 100.

An example of the use of the electronic device 101 is to electrically connect the semiconductor structure 100 to a build-up substrate (not shown) via the solder balls 110 in the electronic device 101.

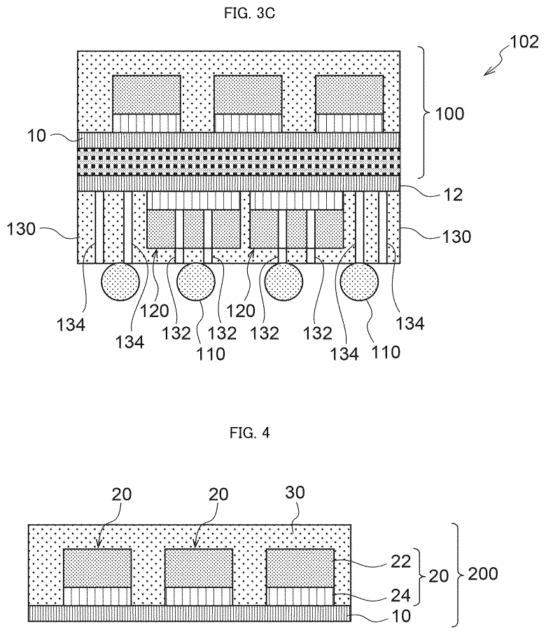

FIGS. 3A to 3C are schematic flow diagrams showing steps of manufacturing another example of an electronic device (electronic device 102) using a semiconductor structure 100 as the first specific example of the semiconductor structure of the disclosure.

To manufacture an electronic device 102, first, as shown in FIG. 3A, an organic bonding layer 12 including an organic insulating layer (not shown) and a metal pad (not shown) is formed on a surface of a semiconductor structure 100 opposite to a side where an organic bonding layer 10 is present as viewed from a redistribution layer 40.

Next, as shown in FIG. 3B, a plurality of silicon bridges 120 are connected to the organic bonding layer 12. Each of the plurality of silicon bridges 120 is connected to the organic bonding layer 12 in an arrangement spanning two adjacent silicon dies 20 in a plan view. As a result, two adjacent silicon dies 20 are electrically connected via one silicon bridge 120. Here, the silicon bridge 120 includes a silicon bridge body 122, a silicon bridge bonding layer 124 that is in contact with the organic bonding layer 12, and through electrodes 126 that penetrate the silicon bridge body 122.

Next, as shown in FIG. 3C, a resin mold 130 is formed so as to cover the organic bonding layer 12 and the plurality of silicon bridges 120, and further, through electrodes 134 are formed to penetrate the resin mold 130. Furthermore, through electrodes 132 are also formed in the portion of the resin mold 130 that covers the plurality of silicon bridges 120. The through electrodes 132 are electrically connected to the through electrodes 126 in the silicon bridges 120.

Next, solder balls 110 are connected to the surface of the resin mold 130. The solder balls 110 are electrically connected to the through electrodes 132 and 134 exposed on the surface of the resin mold 130.

In this manner, the electronic device 102 is obtained.

An example of the use of the electronic device 102 is to electrically connect the semiconductor structure 100 to a build-up substrate (not shown) via the solder balls 110 in the electronic device 102.

As described above, in the electronic device 102, the silicon bridges 120 are covered with the resin mold 130, and the solder balls 110 are connected to the portion of the resin mold 130 that covers the silicon bridges 120.

However, the silicon bridges 120 do not need to be covered by the resin mold 130 and may be exposed (a modified example of the electronic device 102). For example, as shown in FIG. 3C, first, the resin mold 130 may be formed so as to cover the organic bonding layer 12 and the silicon bridges 120, and then the resin mold 130 may be polished by CMP or the like so as to expose the silicon bridges 120, and then the through electrodes 134 may be formed. In this case, the solder balls 110 are directly connected onto the exposed silicon bridges 120.

### Second Specific Example

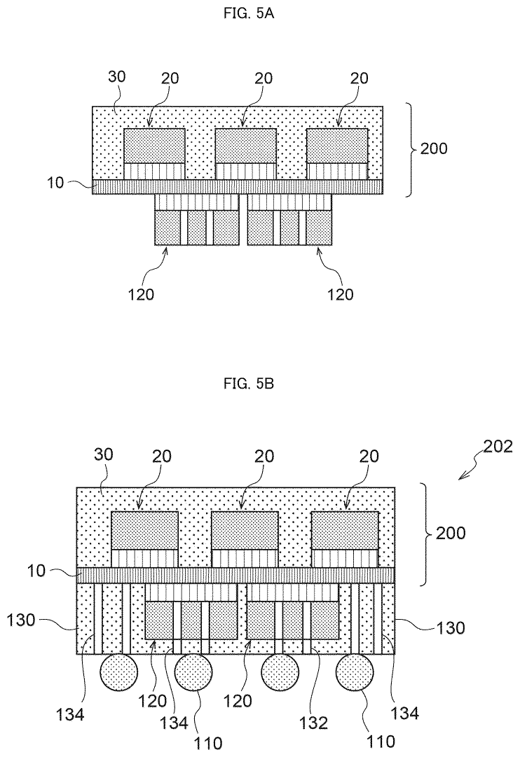

FIG. 4 is a schematic cross-sectional view of a semiconductor structure 200 as the second specific example of the semiconductor structure of the disclosure.

As shown in FIG. 4, the semiconductor structure 200 includes:
an organic bonding layer 10 that includes an organic insulating layer (not shown) and a metal pad (not shown);
a plurality of silicon dies 20 that are arranged in a two-dimensional manner on the organic bonding layer 10 and hybrid-bonded thereto; and
a resin mold layer 30 that is filled between the plurality of silicon dies 20 on the organic bonding layer 10 and covers upper surfaces of the plurality of silicon dies 20.

The configuration of the semiconductor structure 200 is the same as the configuration of the semiconductor structure 100 except that the redistribution layer 40 is absent.

In the semiconductor structure 200, the silicon dies 20 are hybrid-bonded onto the organic bonding layer 10, allowing for the narrowing of the wiring pitch, compared to a case in which the bonding of a semiconductor chip (e.g., silicon die) onto a redistribution layer or a bonding layer is carried out using a solder and an epoxy resin.

The semiconductor structure 200 is connected to a build-up substrate for use.

Hereinafter, examples of the type of usage of the semiconductor structure 200 will be described.

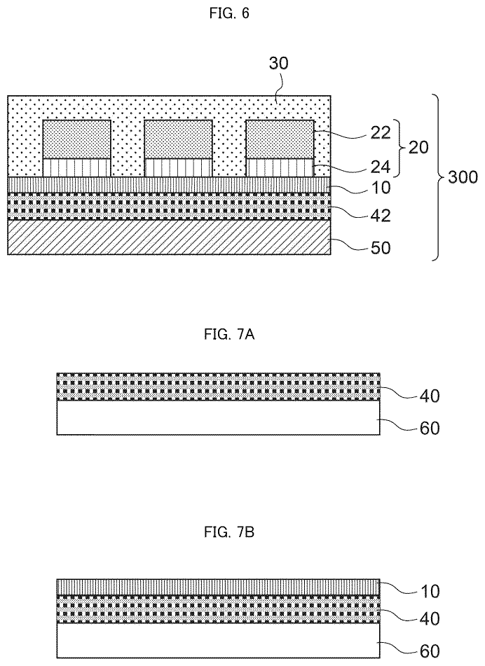

FIGS. 5A to 5B are schematic flow diagrams showing steps of manufacturing another example of an electronic device (electronic device 202) using a semiconductor structure 200 as the second specific example of the semiconductor structure of the disclosure.

To manufacture the electronic device 202, first, as shown in FIG. 5A, a plurality of silicon bridges 120 are connected to the organic bonding layer 10 in a semiconductor structure 200. Each of the plurality of silicon bridges 120 is connected to the organic bonding layer 10 in an arrangement spanning two adjacent silicon dies 20 in a plan view. As a result, two adjacent silicon dies 20 are electrically connected via one silicon bridge 120. Here, the silicon bridge 120 includes a silicon bridge body 122, a silicon bridge bonding layer 124 that is in contact with the organic bonding layer 12, and through electrodes 126 that penetrate the silicon bridge body 122.

Next, as shown in FIG. 5B, a resin mold 130 is formed so as to cover the organic bonding layer 10 and the plurality of silicon bridges 120, and further, through electrodes 134 are formed to penetrate the resin mold 130. Furthermore, through electrodes 132 are also formed in the portion of the resin mold 130 that covers the plurality of silicon bridges 120. The through electrodes 132 are electrically connected to the through electrodes 126 in the silicon bridges 120.

Next, solder balls 110 are connected to the surface of the resin mold 130. The solder balls 110 are electrically connected to the through electrodes 132 and 134 exposed on the surface of the resin mold 130.

In this manner, the electronic device 202 is obtained.

An example of the use of the electronic device 202 is to electrically connect the semiconductor structure 200 to a build-up substrate (not shown) via the solder balls 110 in the electronic device 202.

### Third Specific Example

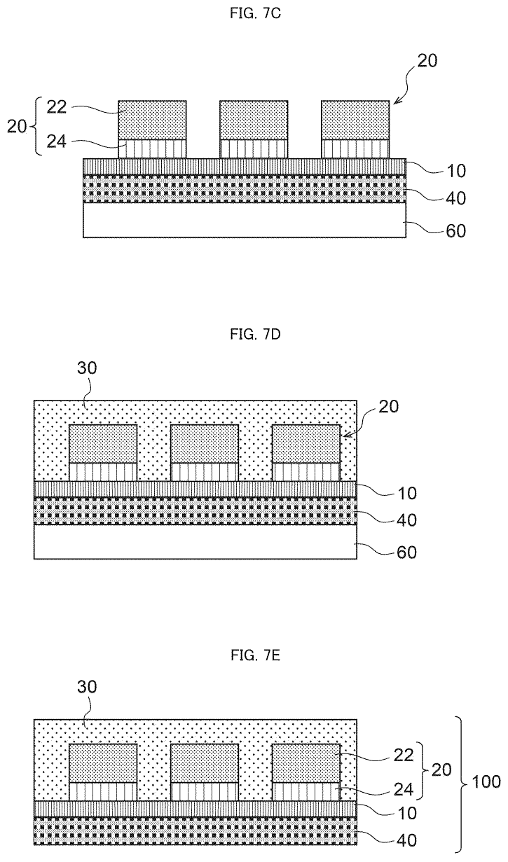

FIG. 6 is a schematic cross-sectional view of a semiconductor structure 300 as the third specific example of the semiconductor structure of the disclosure.

As shown in FIG. 6, the semiconductor structure 300 includes:
an organic bonding layer 10 that includes an organic insulating layer (not shown) and a metal pad (not shown);
a plurality of silicon dies 20 that are arranged in a two-dimensional manner on the organic bonding layer 10 and hybrid-bonded thereto;
a resin mold layer 30 that is filled between the plurality of silicon dies 20 on the organic bonding layer 10 and covers upper surfaces of the plurality of silicon dies 20;
a high-density wiring layer 42 that is arranged at a side opposite to a side at which the plurality of silicon dies 20 are arranged as viewed from the organic bonding layer 10; and
a build-up substrate 50 that is connected to a side opposite to a side at which the organic bonding layer 10 is arranged as viewed from the high-density wiring layer 42.

### [Method of Manufacturing Semiconductor Structure]

Embodiments of the manufacturing method of manufacturing the semiconductor structure of the disclosure described above will be described.

Note that the manufacturing method is not limited to the following embodiments.

### First Embodiment

A method of manufacturing a semiconductor structure according to a first embodiment includes:
a step of forming a redistribution layer on a temporary fixing substrate;
a step of forming an organic bonding layer including an organic insulating layer and a metal pad on the redistribution layer that is temporarily fixed onto the temporary fixing substrate;
a step of arranging a plurality of silicon dies in a two-dimensional manner on the organic bonding layer formed on the redistribution layer and hybrid-bonding the silicon dies thereto;
a step of forming a resin mold layer that is filled between the plurality of silicon dies on the organic bonding layer and covers upper surfaces of the plurality of silicon dies; and
a step of removing the temporary fixing substrate.

The method of manufacturing a semiconductor structure according to the first embodiment is particularly preferable as the method of manufacturing a semiconductor structure 100 according to the first specific example described above.

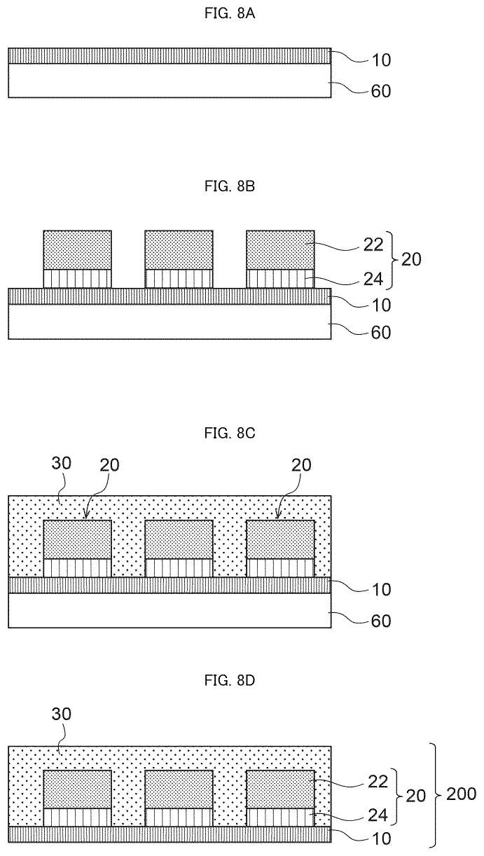

FIGS. 7A to 7E are schematic flow diagrams illustrating a step of manufacturing a semiconductor structure 100 according to the first specific example of the semiconductor structure of the disclosure.

First, as shown in FIG. 7A, a redistribution layer 40 is formed on a temporary fixing substrate 60.

Next, as shown in FIG. 7B, an organic bonding layer 10 including an organic insulating layer and a metal pad is formed on the redistribution layer 40 that is temporarily fixed on the temporary fixing substrate 60.

Next, as shown in FIG. 7C, a plurality of silicon dies 20 are arranged in a two-dimensional manner on the organic bonding layer 10 formed on the redistribution layer 40 and hybrid-bonded thereto. The hybrid bonding is carried out by placing the silicon die bonding layer 24 of the silicon die 20 in contact with the organic bonding layer 10.

Next, as shown in FIG. 7D, a resin mold layer 30 that is filled between the plurality of silicon dies 20 on the organic bonding layer 10 and covers upper surfaces of the plurality of silicon dies 20 is formed.

Next, as shown in FIG. 7E, as a result of removing the temporary fixing substrate 60, a semiconductor structure 100 is obtained.

In the disclosure, as the temporary fixing substrate (e.g., temporary fixing substrate 60), for example, a glass substrate, a silicon substrate, or the like can be used.

In the disclosure, the temporary fixing substrate (e.g., temporary fixing substrate 60) can be removed by a method such as laser lift-off or mechanical peeling.

The method of manufacturing a semiconductor structure according to the first embodiment may further include:
a step of forming an electrode at a side at which the temporary fixing substrate of the redistribution layer is removed; and
a step of bonding the redistribution layer and a build-up substrate via the electrode.

### Second Embodiment

A method of manufacturing a semiconductor structure according to a second embodiment includes:
a step of forming an organic bonding layer including an organic insulating layer and a metal pad on a temporary fixing substrate;
a step of arranging a plurality of silicon dies in a two-dimensional manner on the organic bonding layer formed on the temporary fixing substrate and hybrid-bonding the silicon dies thereto:
a step of forming a resin mold layer that is filled between the plurality of silicon dies on the organic bonding layer and covers upper surfaces of the plurality of silicon dies; and
a step of removing the temporary fixing substrate.

The method of manufacturing a semiconductor structure according to the second embodiment is particularly preferable as, for example, a method of manufacturing the semiconductor structure 200 according to the second specific example described above.

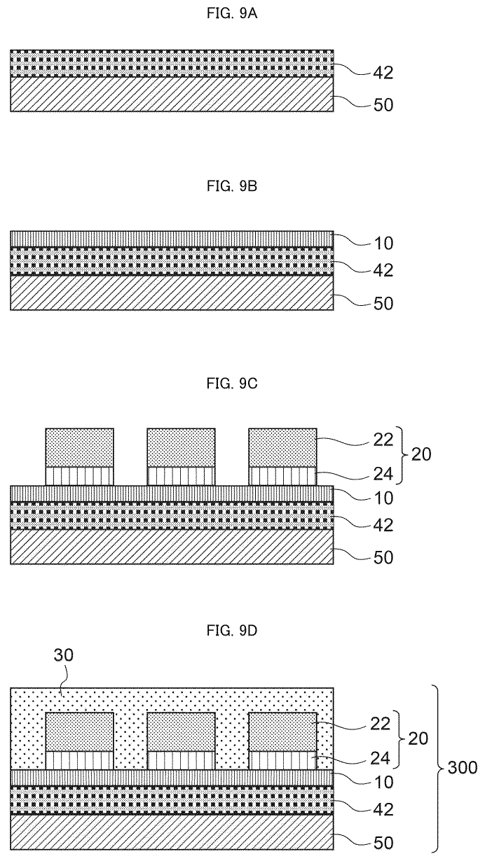

FIGS. 8A to 8D are schematic flow diagrams illustrating a step of manufacturing a semiconductor structure 200 according to the second specific example of the semiconductor structure of the disclosure.

First, as shown in FIG. 8A, an organic bonding layer 10 including an organic insulating layer and a metal pad is formed on a temporary fixing substrate 60.

Next, as shown in FIG. 8B, a plurality of silicon dies 20 are arranged in a two-dimensional manner on the organic bonding layer 10 formed on the temporary fixing substrate 60 and hybrid-bonded thereto. The hybrid bonding is carried out by placing the silicon die bonding layer 24 of the silicon die 20 in contact with the organic bonding layer 10.

Next, as shown in FIG. 8C, a resin mold layer 30 that is filled between the plurality of silicon dies 20 on the organic bonding layer 10 and covers upper surfaces of the plurality of silicon dies 20 is formed.

Next, as shown in FIG. 8D, as a result of removing the temporary fixing substrate 60, a semiconductor structure 200 is obtained.

The method of manufacturing a semiconductor structure according to the second embodiment may further include:
a step of forming an electrode at a side at which the temporary fixing substrate of the organic bonding layer is removed; and
a step of bonding the redistribution layer and a build-up substrate via the electrode.

### Third Embodiment

A method of manufacturing a semiconductor structure according to a third embodiment includes:
a step of forming a high-density wiring layer on a build-up substrate;
a step of forming an organic bonding layer including an organic insulating layer and a metal pad on the high-density wiring layer:
a step of arranging a plurality of silicon dies in a two-dimensional manner on the organic bonding layer formed on the high-density wiring layer and hybrid-bonding the silicon dies thereto; and
a step of forming a resin mold layer that is filled between the plurality of silicon dies on the organic bonding layer and covers upper surfaces of the plurality of silicon dies; and

The method of manufacturing a semiconductor structure according to the third embodiment is particularly preferable as, for example, a method of manufacturing the semiconductor structure 300 according to the third specific example described above.

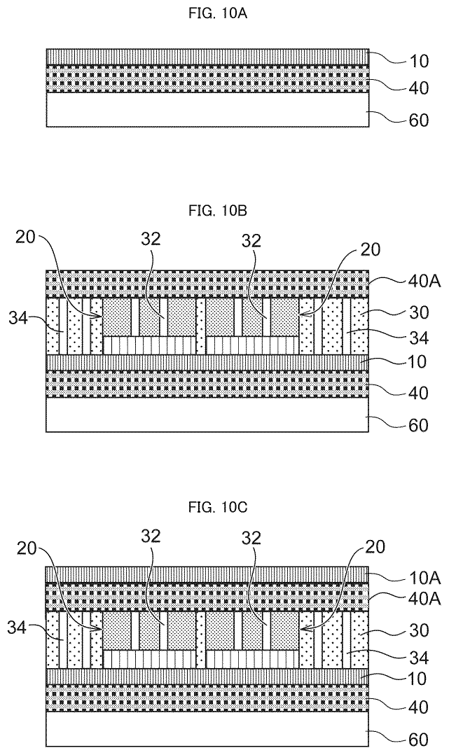

FIGS. 9A to 9D are schematic flow diagrams illustrating a step of manufacturing a semiconductor structure 300 according to the third specific example of the semiconductor structure of the disclosure.

First, as shown in FIG. 9A, a high-density wiring layer 42 is formed on a build-up substrate 50.

Next, as shown in FIG. 9B, an organic bonding layer 10 including an organic insulating layer and a metal pad is formed on the high-density wiring layer 42.

Next, as shown in FIG. 9C, a plurality of silicon dies 20 are arranged in a two-dimensional manner on the organic bonding layer 10 formed on the high-density wiring layer 42 and hybrid-bonded thereto. The hybrid bonding is carried out by placing the silicon die bonding layer 24 of the silicon die 20 in contact with the organic bonding layer 10.

Next, as shown in FIG. 9D, a resin mold layer 30 that is filled between the plurality of silicon dies 20 on the organic bonding layer 10 and covers upper surfaces of the plurality of silicon dies 20 is formed.

In this manner, the semiconductor structure 300 is obtained.

### <Formation of Second Organic Bonding Layer>

The methods of manufacturing a semiconductor structure according to the first to third embodiments may further include:
a step of removing a portion of the resin mold layer that covers the upper surfaces of the plurality of silicon dies so as to expose the upper surfaces of the plurality of silicon dies; and
a step of forming a second organic bonding layer including an organic insulating layer and a metal pad on the plurality of silicon dies having the upper surfaces exposed and the resin mold layer.

Preferred aspects of the second organic bonding layer are the same as preferred aspects of the organic bonding layer described above.

### <Formation of Second Redistribution Layer>

The methods of manufacturing a semiconductor structure according to the first to third embodiments in the case of including the step of forming a second organic bonding layer described above may further include, between the step of exposing the upper surfaces of the plurality of silicon dies and the step of forming a second organic bonding layer, a step of forming a second redistribution layer on the plurality of silicon dies having the upper surfaces exposed and the resin mold layer.

Preferred aspects of the second redistribution layer are the same as preferred aspects of the redistribution layer described above.

### <Hybrid Bonding of Second Silicon Die>

The methods of manufacturing a semiconductor structure according to the first to third embodiments in the case of including the step of forming a second organic bonding layer described above may further include
a step of arranging a plurality of second silicon dies in a two-dimensional manner on the second organic bonding layer and hybrid-bonding the second silicon dies thereto.

Preferred aspects of the second silicon die are the same as preferred aspects of the silicon die described above.

### <Step of Manufacturing Fourth Specific Example>

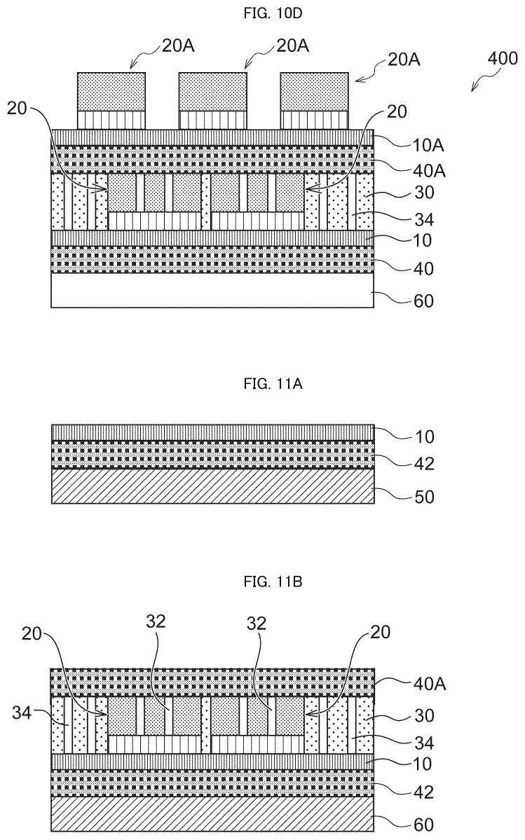

FIGS. 10A to 10D are schematic flow diagrams illustrating a step of manufacturing a semiconductor structure 400 according to the fourth specific example of the semiconductor structure of the disclosure.

The semiconductor structure 400 according to the fourth specific example is provided with the second organic bonding layer, the second redistribution layer, and the second silicon dies described above.

First, as shown in FIG. 10A, an organic bonding layer 10 including an organic insulating layer and a metal pad is formed on a redistribution layer 40 that is temporarily fixed on a temporary fixing substrate 60 as in the step shown in FIG. 7B.

Next, the operation shown in FIG. 10B is carried out.

For more details, as shown in FIG. 10B, a plurality of silicon dies 20 are arranged in a two-dimensional manner on the organic bonding layer 10 formed on the redistribution layer 40 and hybrid-bonded thereto.

Then, a resin mold layer 30 that is filled between the plurality of silicon dies 20 on the organic bonding layer 10 and covers upper surfaces of the plurality of silicon dies 20 is formed.

Then, a portion of the resin mold layer 30 that covers the upper surfaces of the plurality of silicon dies 20 are removed so as to expose the upper surfaces of the plurality of silicon dies. Then, a through electrode 34 that penetrates the resin mold layer 30 and a through electrode 32 that penetrates the silicon die body of the silicon die 20 are formed.

Then, a second redistribution layer 40A is formed on the plurality of silicon dies 20 and the resin mold layer 30 whose upper surfaces are exposed (see FIG. 10B).

Next, as shown in FIG. 10C, a second organic bonding layer 10A including an organic insulating layer and a metal pad is formed on the second redistribution layer 40A.

Next, as shown in FIG. 10D, a plurality of silicon dies 20A are arranged in a two-dimensional manner on the second organic bonding layer 10A and hybrid-bonded thereto.

Thus, a semiconductor structure 400 including the second organic bonding layer 10A, the second redistribution layer 40A, and the second silicon die 20A is manufactured.

In the fourth specific example, the second redistribution layer is an optional element and may be omitted.

Moreover, the temporary fixing substrate 60 may then be removed from the semiconductor structure 400 according to the fourth specific example.

### <Step of Manufacturing Fifth Specific Example>

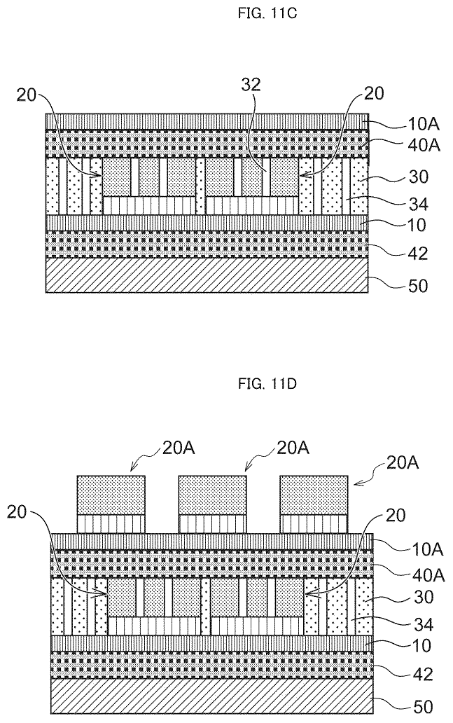

FIGS. 11A to 11D are schematic flow diagrams illustrating a step of manufacturing a semiconductor structure 500 according to the fifth specific example of the semiconductor structure of the disclosure.

The semiconductor structure 500 according to the fifth specific example is also provided with the second organic bonding layer, the second redistribution layer, and the second silicon dies described above as in the semiconductor structure 400 according to the fourth specific example.

First, as shown in FIG. 11A, an organic bonding layer 10 including an organic insulating layer and a metal pad is formed on a high-density wiring layer 42 formed on a build-up substrate 50 as in the step shown in FIG. 9B.

Next, the operation shown in FIG. 11B is carried out.

For more details, as shown in FIG. 11B, a plurality of silicon dies 20 are arranged in a two-dimensional manner on the organic bonding layer 10 formed on the high-density wiring layer 42 and hybrid-bonded thereto.

Then, a resin mold layer 30 that is filled between the plurality of silicon dies 20 on the organic bonding layer 10 and covers upper surfaces of the plurality of silicon dies 20 is formed.

Then, a portion of the resin mold layer 30 that covers the upper surfaces of the plurality of silicon dies 20 are removed so as to expose the upper surfaces of the plurality of silicon dies. Then, a through electrode 34 that penetrates the resin mold layer 30 and a through electrode 32 that penetrates the silicon die body of the silicon die 20 are formed.

Then, a second redistribution layer 40A is formed on the plurality of silicon dies 20 and the resin mold layer 30 whose upper surfaces are exposed (see FIG. 11B).

Next, as shown in FIG. 11C, a second organic bonding layer 10A including an organic insulating layer and a metal pad is formed on the second redistribution layer 40A.

Next, as shown in FIG. 11D, a plurality of silicon dies 20A are arranged in a two-dimensional manner on the second organic bonding layer 10A and hybrid-bonded thereto.

Thus, a semiconductor structure 500 including the second organic bonding layer 10A, the second redistribution layer 40A, and the second silicon die 20A is manufactured.

In the fifth specific example, the second redistribution layer is an optional element and may be omitted.

### <Preferred Aspect of Step of Forming Organic Bonding Layer>

In the methods of manufacturing a semiconductor structure according to the first to third embodiments, the step of forming an organic bonding layer preferably includes forming an organic insulating layer by curing a composition A or B described below.

Thus, an organic insulating layer containing a cured product of the composition A or a cured product of the composition B is formed.

The same applies to the step of forming a second organic bonding layer in the step of manufacturing the fourth specific example and the step of manufacturing the fifth specific example.

### [Composition for Forming Organic Insulating Layer]

The compositions A and B, which are specific examples of compositions for forming an organic insulating layer in the disclosure, will be described below.

The following composition A is a composition described in WO 2022/054839, and composition B is a composition described in Japanese Patent Application Laid-Open (JP-A) No. 2021-182621.

### <Composition A>

The composition A is a composition containing: a compound (A) having an Si—O bond and a cationic functional group containing at least one selected from a primary nitrogen atom or a secondary nitrogen atom, a compound (B) having three or more —C(═O)OX groups (wherein X is a hydrogen atom or an alkyl group having from 1 to 6 carbon atoms), and among the three or more —C(═O)OX groups, one to six are —C(═O)OH groups; and a compound (C) having a ring structure and one or more primary nitrogen atoms directly bonded to the ring structure, in which the ratio of the primary nitrogen atom and secondary nitrogen atom contained in the compound (A) to a total of the primary nitrogen atom and secondary nitrogen atom contained in the compound (A) and the primary nitrogen atoms contained in the compound (C) is from 3% by mole to 95% by mole, and

The above-described composition A contains the compounds (A) and (C) as two different components that react with the compound (B). As a result of intensive studies by the inventors, it was found that the cured product obtained by using this composition A has a lower coefficient of thermal expansion (CTE) than that of the cured product obtained by using only the compound (A) as a component that reacts with the compound (B). For this reason, it is believed that a laminated body obtained using the composition A is less susceptible to distortion at the bonding surface between the layer consisting of the composition A and the substrate, and is therefore excellent in reliability.

The layer obtained by using the composition A also has excellent bonding strength to the substrate.

### (Compound (A))

The compound (A) has an Si—O bond and a cationic functional group containing at least one of a primary nitrogen atom or a secondary nitrogen atom. The cationic functional group is not particularly limited as long as it is a functional group that can bear a positive charge and contains at least one of a primary nitrogen atom or a secondary nitrogen atom.

The cationic functional group containing at least one of a primary nitrogen atom or a secondary nitrogen atom contained in the compound (A) reacts with a carboxy group of the compound (B), thereby forming a cured product. The Si—O bond contained in the compound (A) contributes to improving the bonding strength with the substrate.

The compound (A) may be used singly, or in combination of two or more kinds thereof.

The compound (A) may contain a tertiary nitrogen atom in addition to the primary and secondary nitrogen atoms.

In the disclosure, the “primary nitrogen atom” refers to a nitrogen atom bonded to only two hydrogen atoms and one atom other than a hydrogen atom (e.g., a nitrogen atom contained in a primary amino group (—NH₂ group)), or a nitrogen atom bonded to only three hydrogen atoms and one atom other than a hydrogen atom (cation).

The “secondary nitrogen atom” refers to a nitrogen atom bonded to only one hydrogen atom and two atoms other than hydrogen atoms (i.e., a nitrogen atom contained in a functional group represented by the following Formula (a)), or a nitrogen atom (cation) bonded to only two hydrogen atoms and two atoms other than hydrogen atoms.

The “tertiary nitrogen atom” refers to a nitrogen atom bonded to only three atoms other than hydrogen atoms (i.e., a nitrogen atom that is a functional group represented by the following Formula (b)), or a nitrogen atom (cation) bonded to one hydrogen atom and only three atoms other than hydrogen atoms.

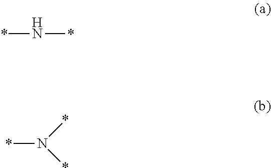

In Formulas (a) and (b), * indicates the position of a bond to an atom other than a hydrogen atom.

The functional group represented by Formula (a) may be a functional group constituting a part of a secondary amino group (—NHR^{a} group; here, R represents an alkyl group), or may be a divalent linking group contained in the polymer skeleton.

The functional group represented by Formula (b) (i.e., a tertiary nitrogen atom) may be a functional group constituting a part of a tertiary amino group (—NR^{b}R^{c} group; here, R^{b} and R^{c} each independently represent an alkyl group), or may be a trivalent linking group contained in the polymer skeleton.

From the viewpoint of decreasing the water absorption rate of the cured product and reducing the amount of outgassing, the compound (A) preferably has two alkyl groups bonded to the oxygen atom constituting the Si—O bond, and more preferably has an alkyl group bonded to each of the two oxygen atoms bonded to one silicon atom constituting the Si—O bond. The two alkyl groups each independently preferably have from 1 to 5 carbon atoms, more preferably 1 or 2 carbon atoms, and still more preferably 2 carbon atoms.

The weight average molecular weight of the compound (A) is not particularly limited. For example, it may be from 130 to 10,000, from 130 to 5,000, or from 130 to 2,000.

In the disclosure, the weight average molecular weight of a compound refers to the weight average molecular weight in terms of polyethylene glycol measured by gel permeation chromatography (GPC).

Specifically, the weight average molecular weight is calculated by analytical software (EMPOWER3, manufactured by Waters) using an aqueous solution of sodium nitrate having a concentration of 0.1 mol/L as a developing solvent, SHODEX DET RI-101 as an analyzer with two types of analytical columns (TSKGEL G6000PWXL-CP AND TSKGEL G3000PWXL-CP, manufactured by Tosoh Corporation) for detecting the refractive index at a flow rate of 1.0 mL/min. and polyethylene glycol/polyethylene oxide as a standard.

The compound (A) may further have an anionic functional group, a nonionic functional group, or the like, as necessary.

The nonionic functional group may be a hydrogen bond accepting group or a hydrogen bond donating group. Examples of the nonionic functional group include a hydroxy group, a carbonyl group, and an ether group (—O—).

The anionic functional group is not particularly limited as long as it is a functional group that can bear a negative charge. Examples of the anionic functional group include a carboxylic acid group, a sulfonic acid group, and a sulfate group.

Specific examples of the compound (A) include compounds having a Si—O bond and an amino group. Examples of compounds having an Si—O bond and an amino group include a siloxane diamine, a silane coupling agent having an amino group, and a siloxane polymer of a silane coupling agent having an amino group.

An example of the silane coupling agent having an amino group is a compound represented by the following Formula (A-3).

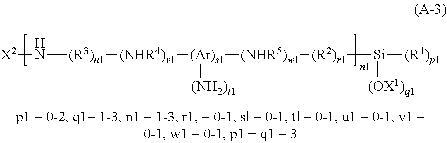

In formula (A-3). R¹ represents an optionally substituted alkyl group having from 1 to 4 carbon atoms. R² and R³ each independently represent an optionally substituted (which may contain a carbonyl group, ether group, or the like in the skeleton) alkylene group having from 1 to 12 carbon atoms, an ether group, or a carbonyl group. R⁴ and R⁵ each independently represent an optionally substituted alkylene group having from 1 to 4 carbon atoms or a single bond. Ar represents a divalent or trivalent aromatic ring. X¹ represents hydrogen or an optionally substituted alkyl group having from 1 to 5 carbon atoms. X₂ represents a hydrogen atom, a cycloalkyl group, a heterocyclic group, an aryl group, or an optionally substituted alkyl group (which may contain a carbonyl group, an ether group, or the like in the skeleton) having from 1 to 5 carbon atoms. A plurality of R¹, R², R³, R⁴, R⁵, and X¹ may be the same or different.

Substituents of the alkyl group and the alkylene group in R¹, R², R³, R⁴, R⁵, X¹, and X² each independently include an amino group, a hydroxy group, an alkoxy group, a cyano group, a carboxylic acid group, a sulfonic acid group, and a halogen.

Examples of the divalent or trivalent aromatic ring for Ar include a divalent or trivalent benzene ring. Examples of the aryl group in X² include a phenyl group, a methylbenzyl group, and a vinylbenzyl group.

Specific examples of silane coupling agents represented by Formula (A-3) include N-(2-aminoethyl)-3-aminopropylmethyldiethoxysilane, N-(2-aminoethyl)-3-aminopropyltriethoxysilane. N-(2-aminoethyl)-3-aminoisobutyldimethylmethoxysilane. N-(2-aminoethyl)-3-aminoisobutylmethyldimethoxysilane, N-(2-aminoethyl)-11-aminoundecyltrimethoxysilane, 3-aminopropyltrimethoxysilane, 3-aminopropyltriethoxysilane, N-phenyl-3-aminopropyltrimethoxysilane, (aminoethylaminoethyl)phenyltriethoxysilane, methylbenzylaminoethylaminopropyltrimethoxysilane, benzylaminoethylaminopropylmethoxysilane, 3-ureidopropyltriethoxysilane, (aminoethylaminoethyl)phenethyltrimethoxysilane, (aminoethylaminomethyl)phenethyltrimethoxysilane, N-[2-[3-(trimethoxysilyl)propylamino]ethyl]ethylenediamine, 3-aminopropyldiethoxymethylsilane, 3-aminopropyldimethoxymethylsilane, 3-aminopropyldimethylethoxysilane, 3-aminopropyldimethylmethoxysilane, trimethoxy[2-(2-aminoethyl)-3-aminopropyl]silane, diaminomethyl methyldiethoxysilane, methylaminomethyl methyldiethoxysilane, p-aminophenyltrimethoxysilane, N-methylaminopropyltriethoxysilane, N-methylaminopropylmethyldiethoxysilane, (phenylaminomethyl)methyldiethoxysilane, acetamidopropyltrimethoxysilane, and hydrolysates thereof.

Examples of silane coupling agents containing an amino group other than those represented by Formula (A-3) include N,N-bis[3-(trimethoxysilyl)propyl]ethylenediamine, N,N′-bis[3-(trimethoxysilyl)propyl]ethylenediamine, bis[(3-triethoxysilyl)propyl]amine, piperazinylpropylmethyldimethoxysilane, bis[3-(triethoxysilyl)propyl]urea, bis(methyldiethoxysilylpropyl)amine, 2,2-dimethoxy-1,6-diaza-2-silacyclooctane, 3,5-diamino-N-(4-(methoxydimethylsilyl)phenyl)benzamnide, 3,5-diamino-N-(4-(triethoxysilyl)phenyl)benzamide, 5-(ethoxydimethylsilyl)benzene-1,3-diamine, and hydrolysates thereof.

The above-described silane coupling agents having an amino group may be used singly, or in combination of two or more kinds thereof.

Furthermore, a polymer (siloxane polymer) formed from these silane coupling agents via a siloxane bond (Si—O—Si) may also be used. For example, from a hydrolysis product of 3-aminopropyltrimethoxysilane, a polymer having a linear siloxane structure, a polymer having a branched siloxane structure, a polymer having a cyclic siloxane structure, a polymer having a cage siloxane structure, and the like can be obtained. The cage siloxane structure is represented, for example, by the following Formula (A-1).

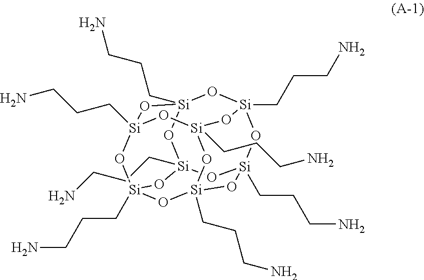 [SMILES: NCCC[Si]12O[Si]3(CCCN)O[Si]4(CCCN)O[Si](CCCN)(O1)O[Si]1(CCCN)O[Si](CCCN)(O2)O[Si](CCCN)(O3)O[Si](CCCN)(O4)O1]

An example of the siloxane diamine is a compound represented by the following Formula (A-2). In Formula (A-2), i is an integer from 0 to 4, j is an integer from 1 to 3, and Me is a methyl group.

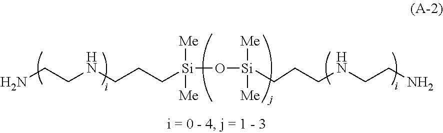

Examples of the siloxane diamine include 1,3-bis(3-aminopropyl)tetramethyldisiloxane (i=0, j=1 in Formula (A-2)) and 1,3-bis(2-aminoethylamino)propyltetramethyldisiloxane (i=1, j=1 in Formula (A-2)).

The compound (A) has a cationic functional group containing at least one of a primary nitrogen atom or a secondary nitrogen atom. Therefore, substrates can be strongly bonded to each other by electrostatic interaction with functional groups such as hydroxyl groups, epoxy groups, carboxy groups, amino groups, and mercapto groups that may be present on the surfaces of the substrates, or by forming close covalent bonds with the functional groups.

In addition, the compound (A) has a cationic functional group containing at least one of a primary nitrogen atom or a secondary nitrogen atom, and therefore has excellent solubility in a polar solvent. Therefore, it has a high affinity with a substrate having a hydrophilic surface such as silicon, and therefore, a smooth film can be formed.

From the viewpoint of heat resistance, the compound (A) is preferably a compound having an amino group as a cationic functional group. Furthermore, from the viewpoint of forming a thermally crosslinked structure such as amide, amide-imide, or imide to further improve heat resistance, a compound having a primary amino group is preferred.

The ratio of the total number of primary nitrogen atoms and secondary nitrogen atoms to the number of silicon atoms in the compound (A) (total number of primary nitrogen atoms and secondary nitrogen atoms/number of silicon atoms) is not particularly limited, but is preferably from 0.2 to 5 from the viewpoint of forming a smooth thin film.

The compound (A) preferably has the molar ratio of Si element in the molecule to a non-crosslinkable group such as a methyl group bonded to the Si element (non-crosslinkable group/Si element) is less than 2 (satisfying the relationship: non-crosslinkable group/Si element <2). By satisfying this condition, it is believed that the crosslinking density (crosslinking between an Si—O—Si bond and an amide bond, imide bond, or the like) of the formed film is improved, resulting in excellent bonding strength.

As described above, the compound (A) has a cationic functional group containing at least one of a primary nitrogen atom or a secondary nitrogen atom. Here, in a case in which the compound (A) contains primary nitrogen atoms, the proportion of primary nitrogen atoms in the total nitrogen atoms in the compound (A) is preferably 20% by mole or more, more preferably 25% by mole or more, and still more preferably 30% by mole or more. In addition, the compound (A) may have a cationic functional group that contains a primary nitrogen atom and does not contain any nitrogen atom other than the primary nitrogen atom (e.g., a secondary nitrogen atom or a tertiary nitrogen atom).

When the proportion of primary nitrogen atoms in the total nitrogen atoms in the compound (A) is 20% by mole or more, dense bonds with functional groups that may be present on the surfaces of substrates are formed, enabling the substrate to be bonded more strongly to each other.

In a case in which the compound (A) contains secondary nitrogen atoms, the proportion of the secondary nitrogen atoms in the total nitrogen atoms in the compound (A) is preferably from 5% by mole to 50% by moles, and more preferably from 5% by mole to 30% by mole.

The compound (A) may contain tertiary nitrogen atoms in addition to primary nitrogen atoms and secondary nitrogen atoms. In a case in which the compound (A) contains tertiary nitrogen atoms, the proportion of the tertiary nitrogen atoms in the total nitrogen atoms in the compound (A) is preferably from 20% by mole to 50% by mole, and more preferably from 25% by mole to 45% by mole.

The content of the compound (A) in the composition A is not particularly limited as long as the proportion of the primary nitrogen atoms and secondary nitrogen atoms contained in the compound (A) to the total of the primary nitrogen atoms and secondary nitrogen atoms contained in the compound (A) and the primary nitrogen atoms contained in the compound (C) is from 3% by mole to 95% by mole.

From the viewpoint of the balance between the coefficient of thermal expansion and the bonding strength, the ratio is preferably from 5% by mole to 75% by mole, and more preferably from 10% by mole to 50% by mole.

### (Compound (B))

The compound (B) is a compound having three or more —C(═O)OX groups (wherein X is a hydrogen atom or an alkyl group having from 1 to 6 carbon atoms) in the molecule, and among the three or more —C(═O)OX groups (hereinafter also referred to as “COOX”), one to six are —C(═O)OH groups (hereinafter also referred to as “COOH”).

When the compound (B) has a —C(═O)OX group (wherein X is a hydrogen atom or an alkyl group having from 1 to 6 carbon atoms) in the molecule, the solubility in the composition A is improved.

The compound (B) may be used singly, or in combination of two or more kinds thereof.

The compound (B) is a compound having three or more —C(═O)OX groups (wherein X is a hydrogen atom or an alkyl group having from 1 to 6 carbon atoms) in the molecule, preferably a compound having three to six —C(═O)OX groups in the molecule, and more preferably a compound having three or four —C(═O)OX groups in the molecule.

When the compound (B) has three or four —C(═O)OX groups in the molecule, it can react efficiently with the compound (A).

In the compound (B), X in the —C(═O)OX group may be a hydrogen atom or an alkyl group having from 1 to 6 carbon atoms, and among these, a hydrogen atom, a methyl group, an ethyl group, and a propyl group are preferred. In addition, X in the —C(═O)OX group may be the same or different.

The compound (B) is a compound having from 1 to 6 —C(═O)OH groups in which X is a hydrogen atom in the molecule, preferably a compound having from 1 to 4 —C(═O)OH groups in the molecule, more preferably a compound having from 2 to 4 —C(═O)OH groups in the molecule, and still more preferably a compound having 2 or 3 —C(═O)OH groups in the molecule.

When the compound (B) has from 1 to 4 —C(═O)OH groups in the molecule, the solubility in composition A is improved.

The weight average molecular weight of the compound (B) is not particularly limited. For example, the weight average molecular weight of the compound (B) may be from 200 to 600, from 200 to 500, from 200 to 450, or from 200 to 400.

When the weight average molecular weight of the compound (B) is within the above range, the solubility in the composition A is improved.

The compound (B) preferably has a ring structure in the molecule. Examples of the ring structure include an alicyclic structure and an aromatic ring structure. In addition, the compound (B) may have a plurality of ring structures in the molecule, and the plurality of ring structures may be the same or different.

When the compound (B) has a ring structure in the molecule, the heat resistance of the cured product is improved.

Examples of the alicyclic structure include an alicyclic structure having from 3 to 8 carbon atoms, and preferably an alicyclic structure having from 4 to 6 carbon atoms, and the ring structure may be saturated or unsaturated. More specific examples of the alicyclic structure include: saturated alicyclic structures such as a cyclopropane ring, a cyclobutane ring, a cyclopentane ring, a cyclohexane ring, a cycloheptane ring, and a cyclooctane ring; and unsaturated alicyclic structures such as a cyclopropene ring, a cyclobutene ring, a cyclopentene ring, a cyclohexene ring, a cycloheptene ring, and a cyclooctene ring.

The aromatic ring structure is not particularly limited as long as it is a ring structure exhibiting aromaticity, and examples thereof include: benzene-based aromatic rings such as a benzene ring, a naphthalene ring, an anthracene ring, and a perylene ring; aromatic heterocycles such as a pyridine ring and a thiophene ring; and non-benzene-based aromatic rings such as an indene ring and an azulene ring.

The ring structure that the compound (B) has in the molecule is preferably at least one selected from the group consisting of a cyclobutane ring, a cyclopentane ring, a cyclohexane ring, a benzene ring, and a naphthalene ring, and from the viewpoint of further increasing the heat resistance of the cured product, at least one of a benzene ring or a naphthalene ring is more preferable.

As described above, the compound (B) may have a plurality of ring structures in the molecule, and in a case in which the ring structure is benzene, it may have a biphenyl structure, a benzophenone structure, a diphenyl ether structure, or the like.

The compound (B) may have a fluorine atom in the molecule. For example, it may have from 1 to 6 fluorine atoms in the molecule, or may have from 3 to 6 fluorine atoms in the molecule. For example, the compound (B) may have a fluoroalkyl group in the molecule, specifically, a trifluoroalkyl group or a hexafluoroisopropyl group.

When the compound (B) has a fluorine atom in the molecule, the water absorption property of the cured product decreases.

Furthermore, examples of the compound (B) include: carboxylic acid compounds such as alicyclic carboxylic acid, benzene carboxylic acid, naphthalene carboxylic acid, diphthalic acid, and fluorinated aromatic ring carboxylic acid; and carboxylic acid ester compounds such as alicyclic carboxylic acid ester, benzene carboxylic acid ester, naphthalene carboxylic acid ester, diphthalic acid ester, and fluorinated aromatic ring carboxylic acid ester. Note that a carboxylic acid ester compound is a compound having a carboxy group (—C(═O)OH group) in the molecule, and having three or more —C(═O)OX groups, in which at least one X is an alkyl group having from 1 to 6 carbon atoms (i.e., having an ester bond).

Since the compound (B) is a carboxylic acid ester compound, aggregation due to association between the compound (A) and the compound (B) is suppressed in the composition A, the number of aggregates and pits is reduced, and adjustment of the film thickness is facilitated.

The carboxylic acid compound is preferably a tetravalent or lower carboxylic acid compound containing 4 or fewer —C(═O)OH groups, and more preferably a trivalent or tetravalent carboxylic acid compound containing three or four —C(═O)OH groups.

The carboxylic acid ester compound is preferably a compound containing 3 or fewer carboxy groups (—C(═O)OH groups) and 3 or fewer ester bonds in the molecule, and more preferably a compound containing 2 or fewer carboxy groups and 2 or fewer ester bonds in the molecule.

In addition, in a case in which X in the three or more —C(═O)OX groups is an alkyl group having from 1 to 6 carbon atoms in the carboxylic acid ester compound, X is preferably a methyl group, an ethyl group, a propyl group, a butyl group, or the like. However, from the viewpoint of further suppressing aggregation due to association between the compound (A) and the compound (B), an ethyl group or a propyl group is preferred.

Specific examples of the carboxylic acid compound include, but are not limited to: alicyclic carboxylic acids such as 1,2,3,4-cyclobutanetetracarboxylic acid, 1,2,3,4-cyclopentanetetracarboxylic acid, 1,3,5-cyclohexanetricarboxylic acid, 1,2,4-cyclohexanetricarboxylic acid, 1,2,4,5-cyclohexanetetracarboxylic acid, and 1,2,3,4,5,6-cyclohexanehexacarboxylic acid; benzene carboxylic acids such as 1,2,4-benzenetricarboxylic acid, 1,3,5-benzenetricarboxylic acid, pyromellitic acid, benzenepentacarboxylic acid, and mellitic acid; naphthalene carboxylic acids such as 1,4,5,8-naphthalene tetracarboxylic acid and 2,3,6,7-naphthalene tetracarboxylic acid; diphthalic acids such as 3,3′,5,5′-tetracarboxydiphenylmethane, biphenyl-3,3′,5,5′-tetracarboxylic acid, biphenyl-3,4′,5-tricarboxylic acid, biphenyl-3,3′,4,4′-tetracarboxylic acid, benzophenone-3,3′,4,4′-tetracarboxylic acid, 4,4′-oxydiphthalic acid, 3,4′-oxydiphthalic acid, 1,3-bis(phthalic acid)tetramethyldisiloxane, 4,4′-(ethyne-1,2-diyl)diphthalic acid, 4,4′-(1,4-phenylenebis(oxy))diphthalic acid, 4,4′-([1,1′-biphenyl]-4,4′-diylbis(oxy))diphthalic acid, and 4,4′-((oxybis(4,1-phenylene))bis(oxy))diphthalic acid; perylene carboxylic acids such as perylene-3,4,9,10-tetracarboxylic acid; Anthracene carboxylic acids such as anthracene-2,3,6,7-tetracarboxylic acid; and fluorinated aromatic ring carboxylic acids such as 4,4′-(hexafluoroisopropylidene)diphthalic acid, 9,9-bis(trifluoromethyl)-9H-xanthene-2,3,6,7-tetracarboxylic acid, and 1,4-ditrifluoromethylpyromellitic acid.

Specific examples of the carboxylic acid ester compound include a compound in which at least one carboxy group in the specific example of the carboxylic acid compound described above is substituted with an ester group. Examples of the carboxylic acid ester compound include half-esterified compounds represented by the following Formulas (B-1) to (B-6).

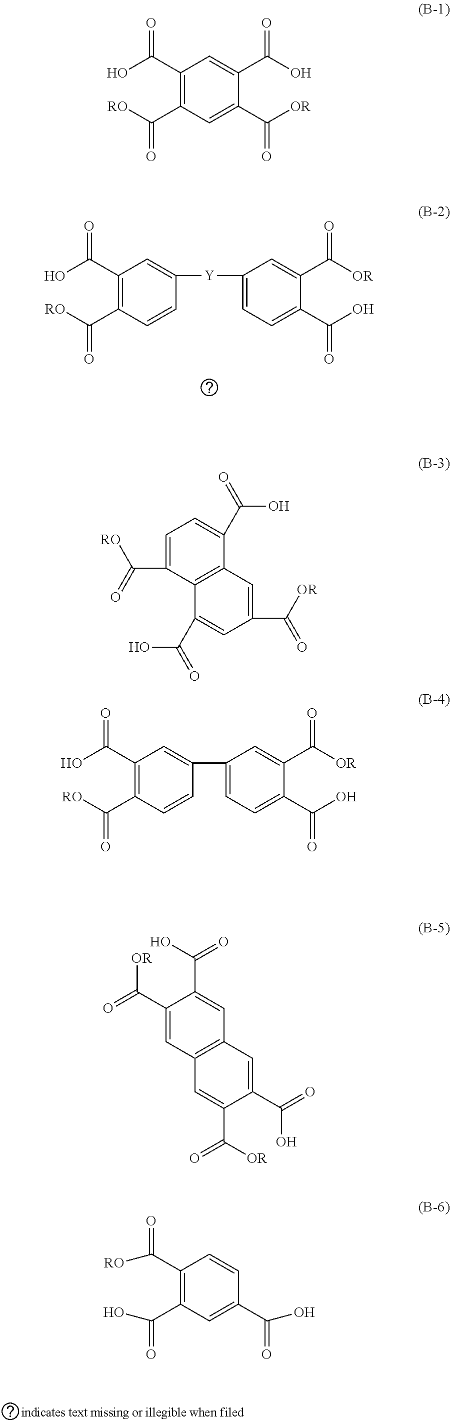

In Formulas (B-1) to (B-6), R is each independently an alkyl group having from 1 to 6 carbon atoms. Among them, a methyl group, an ethyl group, a propyl group, and a butyl group are preferable, and an ethyl group and a propyl group are more preferable.

A half-esterified compound can be produced, for example, by mixing a carboxylic acid anhydride, which is an anhydride of the above-described carboxylic acid compound, with an alcohol solvent and ring-opening the carboxylic acid anhydride.

The content of the compound (B) in the composition A is, for example, an amount such that the ratio (COOH/N) of the carboxy group equivalent number (COOH) of the compound (B) to the total amine equivalent number (N) of the compound (A) and the compound (C) is preferably from 0.1 to 3.0 or less, more preferably from 0.3 to 2.5, and still more preferably from 0.4 to 2.2. When the COOH/N is from 0.1 to 3.0, a crosslinked structure is sufficiently formed by the reaction of the compound (A), the compound (B), and the compound (C), and thus, a cured product having excellent heat resistance and insulating properties tends to be obtained.

### (Compound (C))

The compound (C) is a compound having a ring structure and one or more primary nitrogen atoms directly bonded to the ring structure.

The compound (C) reacts with the compound (A) and the compound (B), thereby forming a cured product.

The compound (C) has a ring structure and one or more primary nitrogen atoms directly bonded to the ring structure. It is believed that the introduction of this structure into a cured product increases the rigidity of the cured product and reduces the coefficient of thermal expansion.

The compound (C) may be used singly, or in combination of two or more kinds thereof.

In the disclosure, the “primary nitrogen atom directly bonded to a ring structure” refers to a primary nitrogen atom (—NH₂) bonded to a ring structure via a single bond (i.e., not via a carbon atom or the like).

The number of primary nitrogen atoms directly bonded to the ring structure contained in the molecule of the compound (C) is not particularly limited as long as it is one or more. From the viewpoint of increasing the crosslinking density, it is preferable that the number of primary amino groups is two or more, and a diamine compound having two primary amino groups or a triamine compound having three primary amino groups is more preferable.

The compound (C) may have one ring structure or a plurality of ring structures in the molecule. In a case in which the compound (C) has a plurality of ring structures in the molecule, each of the ring structures may have a cationic functional group containing a primary nitrogen atom directly bonded thereto, or may have a cationic functional group containing a primary nitrogen atom directly bonded only to one of the ring structures.

In a case in which the compound (C) has a plurality of ring structures in the molecule, the plurality of ring structures may be the same or different, and may form a condensed ring. Alternatively, a plurality of ring structures may be bonded together by a single bond or via a linking group such as an ether group, a carbonyl group, a sulfonyl group, or a methylene group.

Examples of the ring structure contained in the compound (C) include an alicyclic structure, an aromatic ring (including a heterocyclic ring) structure, and condensed ring structures thereof.

The alicyclic structure may be an alicyclic structure having from 3 to 8 carbon atoms, preferably from 4 to 6 carbon atoms. The ring structure may be saturated or unsaturated. More specific examples thereof include: saturated alicyclic structures such as a cyclopropane ring, a cyclobutane ring, a cyclopentane ring, a cyclohexane ring, a cycloheptane ring, and a cyclooctane ring; and unsaturated alicyclic structures such as a cyclopropene ring, a cyclobutene ring, a cyclopentene ring, a cyclohexene ring, a cycloheptene ring, and a cyclooctene ring.

Examples of the aromatic ring structure include an aromatic ring structure having from 6 to 20 carbon atoms, and preferably from 6 to 10 carbon atoms. Specific examples thereof include: benzene-based aromatic ring structures such as a benzene ring, a naphthalene ring, an anthracene ring, and a perylene ring; and non-benzene-based aromatic ring structures such as a pyridine ring, a thiophene ring, an indene ring, and an azulene ring.

Examples of the heterocyclic structure include a 3- to 10-membered heterocyclic structure, and preferably a 5- or 6-membered heterocyclic structure. Examples of heteroatoms contained in the heterocyclic ring include a sulfur atom, a nitrogen atom, and an oxygen atom, and among these, there may be only one kind or two or more kinds.

Specific examples of the heterocyclic structure include an oxazole ring, a thiophene ring, a pyrrole ring, a pyrrolidine ring, a pyrazole ring, an imidazole ring, a triazole ring, an isocyanuric ring, a pyridine ring, a pyridazine ring, a pyrimidine ring, a pyrazine ring, a piperidine ring, a piperazine ring, a triazine ring, an indole ring, an indoline ring, a quinoline ring, an acridine ring, a naphthyridine ring, a quinazoline ring, a purine ring, and a quinoxaline ring.

The ring structure contained in the molecule of the compound (C) is more preferably a benzene ring, a cyclohexane ring, or a benzoxazole ring.

The ring structure that the compound (C) has in the molecule may have a substituent other than a primary nitrogen atom. For example, it may have an alkyl group having from 1 to 6 carbon atoms, an alkyl group substituted with a halogen atom, or the like.

The weight average molecular weight of the compound (C) is not particularly limited. For example, it may be from 80 to 600, from 90 to 500, or from 100 to 450.

Examples of the compound (C) include alicyclic amines, aromatic ring amines, heterocyclic amines having a nitrogen-containing heterocyclic ring, and amine compounds having both a heterocyclic ring and an aromatic ring.

Specific examples of alicyclic amines include cyclohexylamine and dimethylaminocyclohexane.

Specific examples of aromatic ring amines include diaminodiphenyl ether, xylylene diamine (preferably paraxylylene diamine), diaminobenzene, diaminotoluene, methylenedianiline, dimethyldiaminobiphenyl, bis(trifluoromethyl)diaminobiphenyl, diaminobenzophenone, diaminobenzanilide, bis(aminophenyl)fluorene, bis(aminophenoxy)benzene, bis(aminophenoxy)biphenyl, dicarboxydiaminodiphenylmethane, diaminoresorcin, dihydroxybenzidine, diaminobenzidine, 1,3,5-triaminophenoxybenzene, 2,2′-dimethylbenzidine, and tris(4-aminophenyl)amine.

Specific examples of heterocyclic amines having a nitrogen-containing heterocyclic ring include melamine, ammeline, melam, melem, and tris(4-aminophenyl)amine.

Specific examples of amine compounds having both a heterocyclic ring and an aromatic ring include N2,N4,N6-tris(4-aminophenyl)-1,3,5-triazine-2,4,6-triamine and 2-(4-aminophenyl)benzoxazol-5-amine.

The content of the compound (C) in the composition A is not particularly limited as long as the proportion of the primary nitrogen atoms contained in the compound (A) to the total of the primary nitrogen atoms and secondary nitrogen atoms contained in the compound (A) and the primary nitrogen atoms contained in the compound (C) is from 3% by mole to 95% by mole.

From the viewpoint of the balance between the coefficient of thermal expansion and the bonding strength, the ratio is preferably from 5% by mole to 75% by mole, more preferably from 10% by mole to 50% by mole, and still more preferably from 10% by mole to 30% by mole.

### (Polar Solvent)

The composition A may contain a polar solvent. In the disclosure, the “polar solvent” refers to a solvent having a relative dielectric constant of 5 or more at room temperature (25° C.).

When the composition A contains a polar solvent, the solubility of each component in the composition A is improved.

The polar solvent may be used singly, or in combination of two or more kinds thereof.

Specific examples of the polar solvent include protic solvents such as water and deuterium oxide; alcohols such as methanol, ethanol, 1-propanol, 2-propanol, 1-butanol, 2-butanol, isobutyl alcohol, isopentyl alcohol, cyclohexanol, ethylene glycol, propylene glycol, 2-methoxyethanol, 2-ethoxyethanol, benzyl alcohol, diethylene glycol, triethylene glycol, and glycerin; ethers such as tetrahydrofuran and dimethoxyethane; aldehydes and ketones such as furfural, acetone, ethyl methyl ketone, and cyclohexanone; acid derivatives such as acetic anhydride, ethyl acetate, butyl acetate, ethylene carbonate, propylene carbonate, formaldehyde, N-methylformamide, N,N-dimethylformamide, N-methylacetamide, N,N-dimethylacetamide, N-methyl-2-pyrrolidone, and hexamethylphosphoramide; nitriles such as acetonitrile and propionitrile; nitro compounds such as nitromethane and nitrobenzene; and
sulfur compounds such as dimethyl sulfoxide.

The polar solvent preferably contains a protic solvent, more preferably contains water, and further preferably contains ultrapure water.

In a case in which the composition A contains a polar solvent, the content thereof is not particularly limited, and may be, for example, from 1.0% by mass to 99.99896% by mass, or from 40% by mass to 99.99896% by mass with respect to the composition A as a whole.

### (Additives)

The composition A may optionally contain additives, if necessary. Examples of additives include acids having a carboxy group and a weight average molecular weight of from 46 to 195 and bases having a nitrogen atom and a weight average molecular weight of from 17 to 120 with no ring structure.

It is speculated that the composition A contains an acid having a carboxy group and a weight average molecular weight of from 46 to 195 such that primary or secondary nitrogen atoms of the compound (A) and the compound (C) form an ionic bond with the carboxy group in the acid, thereby suppressing aggregation caused by the association between the compounds (A) and (C) and the compound (B). More specifically, it is speculated that the interaction (e.g., electrostatic interaction) between ammonium ions derived from the compounds (A) and (C) and a carboxylate ion derived from a carboxy group in the acid is stronger than the interaction between ammonium ions derived from the compounds (A) and (C) and a carboxylate ion derived from a carboxy group in the compound (B), causing the aggregation to be suppressed. The present invention is in no way limited by the above-described speculations.

The type of the acid having a carboxy group and a weight average molecular weight of from 46 to 195 is not particularly limited, and examples thereof include monocarboxylic acid compounds, dicarboxylic acid compounds, and oxydicarboxylic acid compounds. More specific examples of the acid include formic acid, acetic acid, malonic acid, oxalic acid, benzoic acid, lactic acid, glycolic acid, glyceric acid, butyric acid, methoxyacetic acid, ethoxyacetic acid, phthalic acid, terephthalic acid, picolinic acid, salicylic acid, and 3,4,5-trihydroxybenzoic acid (excluding those corresponding to the compound (B)).

In a case in which the composition A contains an acid having a weight average molecular weight of from 46 to 195, the content thereof is not particularly limited, but, for example, the content is an amount such that the ratio (COOH/N) of the number of carboxy groups of the acid to the total number of primary and secondary nitrogen atoms of the compounds (A) and (C) is preferably from 0.01 to 10, more preferably from 0.02 to 6, and still more preferably from 0.5 to 3.

It is speculated that composition A contains abase having a nitrogen atom and a weight average molecular weight of from 17 to 120 such that a carboxy group of the compound (B) and an amino group of the base form an ionic bond, thereby suppressing aggregation caused by the association between the compounds (A) and (C) and the compound (B). More specifically, it is speculated that the interaction between a carboxylate ion derived from a carboxy group in the compound (B) and an ammonium ion derived from an amino group in the base is stronger than the interaction between ammonium ions derived from the compounds (A) and (C) and a carboxylate ion derived from a carboxy group in the compound (B), causing the aggregation to be suppressed. The invention is in no way limited by the above-described speculations.

The type of the compound having a nitrogen atom and a weight average molecular weight of from 17 to 120 is not particularly limited, and examples thereof include monoamine compounds and diamine compounds (excluding those corresponding to the compounds (A) and (C)). More specific examples include ammonia, ethylamine, ethanolamine, diethylamine, triethylamine, ethylenediamine, N-acetylethylenediamine, N-(2-aminoethyl)ethanolamine, and N-(2-aminoethyl)glycine.

In a case in which the composition A contains a base having a weight average molecular weight of from 17 to 120, the content thereof is not particularly limited, but for example, the ratio of the number of nitrogen atoms in the base to the number of carboxy groups in the compound (B) (N/COOH) is preferably from 0.5 to 5, and more preferably from 0.9 to 3.

### (Other Components)

In a case in which selectivity of plasma etching resistance is required for the composition A (e.g., a case in which the composition A is used as a gap fill material or a buried insulating film), the composition A may contain a metal alkoxide represented by the following Formula (I):

R1ₙM(OR2)ₘ₋ₙ (I)

(where R1 is a non-hydrolyzable group, R2 is an alkyl group having from 1 to 6 carbon atoms. M represents at least one metal atom selected from the group consisting of Ti, Al, Zr, Sr, Ba, Zn, B, Ga, Y, Ge, Pb, P. Sb, V, Ta, W. La, Nd, and In, m is the valence of the metal atom M, which is 3 or 4, n is an integer from 0 to 2 when m is 4, and is 0 or 1 when m is 3, and when there are a plurality of R1's, R1's may be the same or different from one another, and when there are a plurality of OR2's, OR2's may be the same or different from one another).

In a case in which a film produced from the composition A is required to have insulating properties (e.g., for use as an insulating film for a through-silicon via or as a buried insulating film), the composition A may contain a silane compound (other than any one corresponding to the compound (A)) in order to improve the insulating properties or mechanical strength.

Specific examples of the silane compound include tetraethoxysilane, tetramethoxysilane, bistriethoxysilylethane, bistriethoxysilylmethane, bis(methyldiethoxysilyl)ethane, 1,1,3,3,5,5-hexaethoxy-1,3,5-trisilacyclohexane, 1,3,5,7-tetramethyl-1,3,5,7-tetrahydroxylcyclosiloxane, 1,1,4,4-tetramethyl-1,4-diethoxydisilethylene, 1,3,5-trimethyl-1,3,5-trimethyl-1,3,5-triethoxy-1,3,5-trisilacyclohexane, and silane coupling agents having functional groups other than amino groups (epoxy groups, mercapto groups, and the like).

The composition A may contain a solvent other than the polar solvent. Examples of the solvent other than the polar solvent include normal hexane.

The composition A may contain benzotriazole or a derivative thereof, for example, so as to inhibit copper corrosion.

The pH of the composition A is not particularly limited, but is preferably from 2.0 to 12.0.

When the pH of the composition A is 2.0 or more and 12.0 or less, damage to the substrate caused by the composition A is suppressed.

The composition A preferably has a sodium and potassium content of 10 ppb by mass or less on an elemental basis. As long as the content of sodium or potassium is 10 ppb by mass or less on an elemental basis, the occurrence of problems in the electrical characteristics of the semiconductor device, such as malfunction of a transistor, can be suppressed.

In a case in which the composition A contains components other than compounds (A), (B), and (C), the total mass of compounds (A), (B), and (C) is preferably 50% by mass or more, more preferably 70% by mass or more, and still more preferably 80% by mass or more of the total mass of nonvolatile components in the composition A. In the disclosure, the “non-volatile component” refers to a component other than a component (such as a solvent) that is removed when the composition A becomes a cured product.

### <Composition B>

The composition B contains at least one of a compound (X1) having a structure represented by the following Formula (1) and a molecular weight of from 400 to 5,000 or a compound (X2) having a structure represented by the following Formula (2) and a molecular weight of from 400 to 5,000.

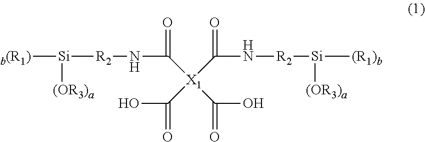

In Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride.

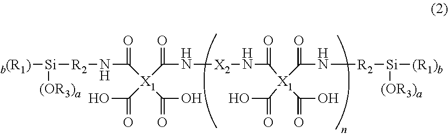

In Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.

According to the above-described composition B, a resin layer having less residual stress can be formed, as compared with the composition B containing a silane coupling agent, a carboxylic acid dianhydride, an amine compound, and the like, which are precursors of the compound (X1) or the compound (X2), in an unreacted state. Although the reason for this is not entirely clear, for example, it is considered that since the precursors of compound (X1) or compound (X2) are in a reacted state before the composition B is applied onto a substrate, the cure shrinkage of the resin layer caused by the reaction is suppressed and the residual stress of the resin layer is reduced, compared to a case in which a resin layer is formed by reacting these precursors on a substrate.

In Formula (1), X₁ is a structure derived from a carboxylic acid dianhydride, and preferably contains a ring structure. In addition, the amide group and the carboxy group bonded to X₁ react on the substrate to form an imide bond. Therefore, the resulting resin layer exhibits excellent heat resistance.

In Formula (1), a is preferably 2.

In Formula (1), examples of the organic group having 6 or fewer carbon atoms represented by R₁ and R₃ include alkyl groups having 6 or fewer carbon atoms, preferably 3 or fewer carbon atoms, and more preferably 2 or fewer carbon atoms.

In Formula (2). X₁ and X₂ are structures derived from a carboxylic acid dianhydride and an amine compound, respectively, and preferably contain a ring structure. In addition, the amide group and the carboxy group bonded to X₁ react on the substrate to form an imide bond. Therefore, the resulting resin layer exhibits excellent heat resistance.

In Formula (2), a is preferably 2.

In Formula (2), examples of the organic group having 6 or fewer carbon atoms represented by R₁ and R₃ include alkyl groups having 6 or fewer carbon atoms, preferably 3 or fewer carbon atoms, and more preferably 2 or fewer carbon atoms.

In Formula (2), n is not particularly limited as long as it is a positive number, and may be, for example, within a range of from 1 to 6.

The compound (X2) represented by Formula (2) may be in a state in which a structure derived from a carboxylic acid dianhydride and a structure derived from an amine compound are arranged alternately (polyamic acid).

The compound (X1) contained in the above-described composition B may be a compound having a structure obtained by reacting a silane coupling agent (A) with a carboxylic acid dianhydride (B) having a molecular weight of from 200 to 600 and a ring structure.

The compound (X2) contained in the above-described composition B may be a compound having a structure obtained by reacting a silane coupling agent (A) with a carboxylic acid dianhydride (B) having a molecular weight of from 200 to 600 and a ring structure and a structure obtained by reacting an amine compound (C) having a molecular weight of from 90 to 600 and a ring structure but no Si—O bond with a carboxylic acid dianhydride (B) having a molecular weight of from 200 to 600 and a ring structure.

In the disclosure, the carboxylic acid dianhydride (B) having a molecular weight of from 200 to 600 and a ring structure and the amine compound (C) having a molecular weight of from 90 to 600 and a ring structure but no Si—O bond may be simply referred to as the carboxylic acid dianhydride (B) and the amine compound (C), respectively.

### (Silane Coupling Agent (A))

The silane coupling agent (A) is a compound that has one or more Si—O bonds in the molecule and reacts with a carboxylic acid dianhydride to produce the compound (X1) or the compound (X2). The Si—O bond contained in the silane coupling agent (A) contributes to improving the bonding strength between the resin layer formed using the composition B and the substrate.

The silane coupling agent (A) is not particularly limited as long as it has a functional group capable of reacting with the anhydride group of the carboxylic acid dianhydride (B).

Specific examples of the functional group include an amino group, an epoxy group, and an isocyanate group. From the viewpoint of the coefficient of thermal expansion and bonding strength of the resin layer, it is preferable that the silane coupling agent (A) has an amino group, and from the viewpoint of forming an imide structure in the resin layer to improve heat resistance, a compound having a primary amino group (—NH₂) is more preferable.

The silane coupling agent (A) may be used singly, or in combination of two or more kinds thereof.

The molecular weight of the silane coupling agent (A) is not particularly limited.

For example, it may be from 130 to 10,000, from 130 to 5,000, or from 130 to 2,000.

An example of the silane coupling agent (A) having an amino group is a compound represented by the following Formula (A-3).

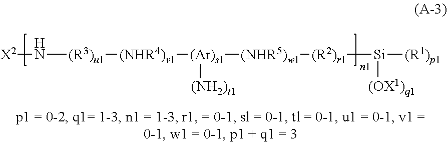

In formula (A-3), R¹ represents an optionally substituted alkyl group having from 1 to 4 carbon atoms. R² and R³ each independently represent an optionally substituted (which may contain a carbonyl group, ether group, or the like in the skeleton) alkylene group having from 1 to 12 carbon atoms, an ether group, or a carbonyl group. R⁴ and R⁵ each independently represent an optionally substituted alkylene group having from 1 to 4 carbon atoms or a single bond. Ar represents a divalent or trivalent aromatic ring. X₁ represents hydrogen or an optionally substituted alkyl group having from 1 to 5 carbon atoms. X₂ represents a hydrogen atom, a cycloalkyl group, a heterocyclic group, an aryl group, or an optionally substituted alkyl group (which may contain a carbonyl group, an ether group, or the like in the skeleton) having from 1 to 5 carbon atoms. A plurality of R¹, R², R³, R⁴, R⁵, and X¹ may be the same or different.

Substituents of the alkyl group and the alkylene group in R¹, R², R³, R⁴, R⁵, X¹, and X² each independently include an amino group, a hydroxy group, an alkoxy group, a cyano group, a carboxylic acid group, a sulfonic acid group, and a halogen.

Examples of the divalent or trivalent aromatic ring for Ar include a divalent or trivalent benzene ring. Examples of the aryl group in X² include a phenyl group, a methylbenzyl group, and a vinylbenzyl group.

Specific examples of silane coupling agents represented by Formula (A-3) include N-(2-aminoethyl)-3-aminopropylmethyldiethoxysilane, N-(2-aminoethyl)-3-aminopropyltriethoxysilane, N-(2-aminoethyl)-3-aminoisobutyldimethylmethoxysilane, N-(2-aminoethyl)-3-aminoisobutylmethyldimethoxysilane, N-(2-aminoethyl)-11-aminoundecyltrimethoxysilane, 3-aminopropyltrimethoxysilane, 3-aminopropyltriethoxysilane, N-phenyl-3-aminopropyltrimethoxysilane, (aminoethylaminoethyl)phenyltriethoxysilane, methylbenzylaminoethylaminopropyltrimethoxysilane, benzylaminoethylaminopropyltriethoxysilane, 3-ureidopropyltriethoxysilane, (aminoethylaminoethyl)phenethyltrimethoxysilane, (aminoethylaminomethyl)phenethyltrimethoxysilane, N-[2-[3-(trimethoxysilyl)propylamino]ethyl]ethylenediamine, 3-aminopropyldiethoxymethylsilane, 3-aminopropyldimethoxymethylsilane, 3-aminopropyldimethylethoxysilane, 3-aminopropyldimethylmethoxysilane, trimethoxy[2-(2-aminoethyl)-3-aminopropyl]silane, diaminomethyl methyldiethoxysilane, methylaminomethyl methyldiethoxysilane, p-aminophenyltrimethoxysilane, N-methylaminopropyltriethoxysilane, N-methylaminopropylmethyldiethoxysilane, (phenylaminomethyl)methyldiethoxysilane, and acetamidopropyltrimethoxysilane.

Examples of silane coupling agents containing an amino group other than those represented by Formula (A-3) include N,N-bis[3-(trimethoxysilyl)propyl]ethylenediamine, N,N′-bis[3-(trimethoxysilyl)propyl]ethylenediamine, bis[(3-triethoxysilyl)propyl]amine, piperazinylpropylmethyldimethoxysilane, bis[3-(triethoxysilyl)propyl]urea, bis(methyldiethoxysilylpropyl)amine, 2,2-dimethoxy-1,6-diaza-2-silacyclooctane, 3,5-diamino-N-(4-(methoxydimethylsilyl)phenyl)benzamide, 3,5-diamino-N-(4-(triethoxysilyl)phenyl)benzamide, and 5-(ethoxydimethylsilyl)benzene-1,3-diamine.

The silane coupling agent (A) having an amino group may be used singly, or in combination of two or more kinds thereof.

### (Carboxylic Acid Dianhydride (B))

The carboxylic acid dianhydride (B) is a compound having one or more ring structures and two anhydride groups in the molecule and having a molecular weight of from 200 to 600.

The molecular weight of the carboxylic acid dianhydride (B) may be from 200 to 400.

The carboxylic acid dianhydride (B) may be used singly, or in combination of two or more kinds thereof.

Examples of the ring structure that the carboxylic acid dianhydride (B) has in the molecule include an alicyclic structure and an aromatic ring (including a heterocyclic ring) structure. The carboxylic acid dianhydride (B) may have one ring structure or a plurality of ring structures in the molecule.

Examples of the alicyclic structure include an alicyclic structure having from 3 to 8 carbon atoms, and preferably an alicyclic structure having from 4 to 6 carbon atoms, and the ring structure may be saturated or unsaturated. More specific examples of the alicyclic structure include: saturated alicyclic structures such as a cyclopropane ring, a cyclobutane ring, a cyclopentane ring, a cyclohexane ring, a cycloheptane ring, and a cyclooctane ring; and unsaturated alicyclic structures such as a cyclopropene ring, a cyclobutene ring, a cyclopentene ring, a cyclohexene ring, a cycloheptene ring, and a cyclooctene ring.

The aromatic ring structure is not particularly limited as long as it is a ring structure exhibiting aromaticity, and examples thereof include: benzene-based aromatic rings such as a benzene ring, a naphthalene ring, an anthracene ring, and a perylene ring; aromatic heterocycles such as a pyridine ring and a thiophene ring; and non-benzene-based aromatic rings such as an indene ring and an azulene ring.

The ring structure that the carboxylic acid dianhydride (B) has in the molecule is preferably at least one selected from the group consisting of a cyclobutane ring, a cyclopentane ring, a cyclohexane ring, a benzene ring, and a naphthalene ring, and from the viewpoint of further increasing the heat resistance of the resin layer, at least one of a benzene ring or a naphthalene ring is more preferable. Furthermore, from the viewpoint of suppressing the occurrence of voids in a resin layer in a case in which a resin layer is formed between a plurality of substrates using the composition B, it is preferable that the composition B contains two or more benzene rings.

In a case in which the carboxylic acid dianhydride (B) has a plurality of ring structures in the molecule, the plurality of ring structures may be the same or different, and may form a condensed ring. Alternatively, a plurality of ring structures may be bonded together by a single bond or via a linking group such as an ether group, a carbonyl group, a sulfonyl group, or a methylene group.

The carboxylic acid dianhydride (B) may have a fluorine atom in the molecule. For example, it may have from 1 to 6 fluorine atoms in the molecule, or may have from 3 to 6 fluorine atoms in the molecule. For example, the carboxylic acid dianhydride (B) may have a fluoroalkyl group in the molecule, specifically, a trifluoroalkyl group or a hexafluoroisopropyl group.

Examples of the carboxylic acid dianhydride (B) include dianhydrides of compounds having a ring structure in the molecule and four carboxy groups capable of forming an anhydride group.

Examples thereof include: anhydrides of alicyclic tetracarboxylic acids such as 1,2,3,4-cyclobutanetetracarboxylic acid, 1,2,3,4-cyclopentanetetracarboxylic acid, 1,2,4,5-cyclohexanetetracarboxylic acid, and 1,2,3,4,5,6-cyclohexanehexacarboxylic acid;
dianhydrides of benzenetetracarboxylic acids such as pyromellitic acid;
dianhydrides of naphthalenetetracarboxylic acids such as 1,4,5,8-naphthalenetetracarboxylic acid and 2,3,6,7-naphthalenetetracarboxylic acid;
dianhydrides of biphenyltetracarboxylic acids such as 3,3′,4,4′-biphenyltetracarboxylic acid;
dianhydrides of benzophenonetetracarboxylic acids such as benzophenone-3,3′,4,4′-tetracarboxylic acid:
dianhydrides of diphthalic acids such as 4,4′-oxydiphthalic acid (ODPA), 3,4′-oxydiphthalic acid, 1,3-bis(phthalic acid) tetramethyldisiloxane, 4,4′-(ethyne-1,2-diyl)diphthalic acid, 4,4′-(1,4-phenylenebis(oxy))diphthalic acid, 4,4′-([1,1′-biphenyl]-4,4′-diylbis(oxy))diphthalic acid, and 4,4′-((oxybis(4,1-phenylene))bis(oxy))diphthalic acid: dianhydrides of perylene carboxylic acids such as perylene-3,4,9,10-tetracarboxylic acid;
dianhydrides of anthracene carboxylic acids such as anthracene-2,3,6,7-tetracarboxylic acid:
dianhydrides of fluorinated aromatic ring carboxylic acids such as 4,4′-(hexafluoroisopropylidene)diphthalic acid, 9,9-bis(trifluoromethyl)-9H-xanthene-2,3,6,7-tetracarboxylic acid, and 1,4-ditrifluoromethylpyromellitic acid;
a dianhydride of bis(1,3-dioxo-1,3-dihydroisobenzofuran-5-carboxylic acid) 1,4-phenylene;
a dianhydride of 4,4′-(4,4′-isopropylidenediphenoxy)diphthalic acid (IPBDA); and
a dianhydride of bis(1,3-dioxo-1,3-dihydroisobenzofuran-5-carboxylic acid) 1,4-phenylene (TAHQ).

The content of carboxylic acid dianhydride (B) in the composition B is an amount such that, for example, the ratio (A/B) of the functional group equivalent number A of the silane coupling agent (A) capable of reacting with the anhydride group of the carboxylic acid dianhydride (B) to the anhydride group equivalent number B of the carboxylic acid dianhydride (B) is preferably from 0.9 to 1.1, more preferably from 0.95 to 1.05, and still more preferably from 0.98 to 1.02.

In a case in which the composition B further contains a compound capable of reacting with the anhydride group of the carboxylic acid dianhydride (B), such as the compound (C) described below, the ratio (A′/B′) of the functional group equivalent number A′ of all compounds capable of reacting with the anhydride group of the carboxylic acid dianhydride (B) to the anhydride group equivalent number B′ of the carboxylic acid dianhydride (B) is preferably from 0.9 to 1.1, more preferably from 0.95 to 1.05, and still more preferably from 0.98 to 1.02.

### (Amine Compound (C))

The amine compound (C) is a compound having one or more ring structures and one or more amino groups in the molecule with no Si—O bond a molecular weight of from 90 to 600.

The amine compound (C) may be used singly, or in combination of two or more kinds thereof.

The number of amino groups in the molecule of the amine compound (C) may be one or more. However, from the viewpoint of reducing the coefficient of thermal expansion of the resin layer, the number of amino groups is preferably more than one, and more preferably two (diamine) or three (triamine). From the viewpoint of forming an imide structure in the resin layer and improving heat resistance, it is more preferable that the resin layer has a primary amino group (—NH₂).

From the viewpoint of reducing the coefficient of thermal expansion of the resin layer, the amine compound (C) preferably has one or more amino groups directly bonded to a ring structure. When the molecular structure of the compound (X2) contains a structure derived from an amino group directly bonded to the ring structure, it is believed that the rigidity of the molecular structure increases, resulting in a further decrease in the coefficient of thermal expansion.

In the disclosure, the “amino group directly bonded to a ring structure” refers to an amino group bonded to a ring structure via a single bond (i.e., not via a carbon atom or the like).

The amine compound (C) may have one ring structure or a plurality of ring structures in the molecule. In a case in which the amine compound (C) has a plurality of ring structures in the molecule, the plurality of ring structures may be the same or different, and may form a condensed ring. Alternatively, a plurality of ring structures may be bonded together by a single bond or via a linking group such as an ether group, a carbonyl group, a sulfonyl group, or a methylene group.

Examples of the ring structure contained in the amine compound (C) include an alicyclic structure, an aromatic ring (including a heterocyclic ring) structure, and condensed ring structures thereof.

Examples of the alicyclic structure include an alicyclic structure having from 3 to 8 carbon atoms, and preferably an alicyclic structure having from 4 to 6 carbon atoms, and the ring structure may be saturated or unsaturated. More specific examples thereof include: saturated alicyclic structures such as a cyclopropane ring, a cyclobutane ring, a cyclopentane ring, a cyclohexane ring, a cycloheptane ring, and a cyclooctane ring; and unsaturated alicyclic structures such as a cyclopropene ring, a cyclobutene ring, a cyclopentene ring, a cyclohexene ring, a cycloheptene ring, and a cyclooctene ring.

Examples of the aromatic ring structure include an aromatic ring structure having from 6 to 20 carbon atoms, and preferably from 6 to 10 carbon atoms. Specific examples thereof include: benzene-based aromatic ring structures such as a benzene ring, a naphthalene ring, an anthracene ring, and a perylene ring; and non-benzene-based aromatic ring structures such as a pyridine ring, a thiophene ring, an indene ring, and an azulene ring.

Examples of the heterocyclic structure include a 3- to 10-membered heterocyclic structure, and preferably a 5- or 6-membered heterocyclic structure. Examples of heteroatoms contained in the heterocyclic ring include a sulfur atom, a nitrogen atom, and an oxygen atom, and among these, there may be only one kind or two or more kinds.

Specific examples of the heterocyclic structure include an oxazole ring, a thiophene ring, a pyrrole ring, a pyrrolidine ring, a pyrazole ring, an imidazole ring, a triazole ring, an isocyanuric ring, a pyridine ring, a pyridazine ring, a pyrimidine ring, a pyrazine ring, a piperidine ring, a piperazine ring, a triazine ring, an indole ring, an indoline ring, a quinoline ring, an acridine ring, a naphthyridine ring, a quinazoline ring, a purine ring, and a quinoxaline ring.

The ring structure contained in the molecule of the amine compound (C) is more preferably a benzene ring, a cyclohexane ring, or a benzoxazole ring.

The ring structure that the amine compound (C) has in the molecule may have a substituent other than an amino group. For example, it may have an alkyl group having from 1 to 6 carbon atoms, an alkyl group substituted with a halogen atom, or the like.

Specific examples of the amine compound (C) include the following compounds.

Examples of alicyclic amines include cyclohexylamine and dimethylaminocyclohexane.

Examples of aromatic ring amines include diaminodiphenyl ether, xylylene diamine (preferably paraxylylene diamine), diaminobenzene, diaminotoluene, methylenedianiline, dimethyldiaminobiphenyl, bis(trifluoromethyl)diaminobiphenyl (TFDB), diaminobenzophenone, diaminobenzanilide, bis(aminophenyl)fluorene, bis(aminophenoxy)benzene, bis(aminophenoxy)biphenyl, dicarboxydiaminodiphenylmethane, diaminoresorcin, dihydroxybenzidine, diaminobenzidine, 1,3,5-triaminophenoxybenzene, 2,2′-dimethylbenzidine, and tris(4-aminophenyl)amine.

Examples of heterocyclic amines having a nitrogen-containing heterocyclic ring include melamine, ammeline, melam, melem, and tris(4-aminophenyl)amine.

Furthermore, examples of amine compounds having both a heterocyclic ring and an aromatic ring include N2,N4,N6-tris(4-aminophenyl)-1,3,5-triazine-2,4,6-triamine and 2-(4-aminophenyl)benzoxazol-5-amine (AAPD).

### (Method of Obtaining Compound (X1))

An example of a method of obtaining a compound (X1) by reacting a silane coupling agent (A) with a carboxylic acid dianhydride (B) is a method in which a silane coupling agent (A) is gradually added dropwise to a carboxylic acid dianhydride (B) in a solvent while stirring, thereby obtaining a compound (X1).

### (Method of Obtaining Compound (X2))

An example of a method of obtaining a compound (X2) by reacting a silane coupling agent (A), a carboxylic acid dianhydride (B), and an amine compound (C) is a method in which a solvent is added to an amine compound (C), and while stirring, a carboxylic acid dianhydride (B) is added, and stirring is continued until the viscosity of the resulting reaction product (polymer) becomes constant, and then a silane coupling agent (A) is gradually added dropwise, thereby obtaining a compound (X2).

### (Precursor of Resin (D))

The composition B may further contain a compound other than the compound (X1) and the compound (X2). For example, it may further contain a precursor of a resin (D) having a CTE of 90 ppm/K or less between 50° C. and 150° C. When the composition B contains a precursor of the resin (D), the coefficient of thermal expansion of the resulting resin layer tends to be further reduced.

Specific examples of the resin (D) having a CTE of 90 ppm/K or less between 50° C. and 150° C. include at least one selected from the group consisting of polyimide and polybenzoxazole.

The CTE of the resin (D) can be measured in the same manner as the CTE of the resin layer.

In a case in which composition B contains the resin (D), the proportion of the resin (D) contained in the composition B is preferably from 99% by mass to 30% by mass of the total non-volatile content of the composition B, from the viewpoint of the balance between the coefficient of thermal expansion and bonding strength of the resulting resin layer. In the disclosure, the “non-volatile component” refers to a component other than a component (such as a solvent) that is removed when the composition B becomes a cured product.

### (Organic Solvent)

The composition B may contain an organic solvent. The organic solvent is not particularly limited as long as it can dissolve the compound (X). Examples thereof include aprotic solvents, phenol-based solvents, ether-based solvents, and glycol-based solvents.

The organic solvent may be used singly, or in combination of two or more kinds thereof.

Specific examples of aprotic solvents include: amide-based solvents such as N,N-dimethylformamide (DMF), N,N-dimethylacetamide (DMAc), N-methyl-2-pyrrolidone (NMP), N-methylcaprolactam, 1,3-dimethylimidazolidinone, and tetramethylurea; lactone-based solvents such as γ-butyrolactone and γ-valerolactone; phosphorus-containing amide-based solvents such as hexamethylphosphoric amide and hexamethylphosphine triamide; sulfur-containing solvents such as dimethyl sulfone, dimethyl sulfoxide, and sulfolane: ketone-based solvents such as cyclohexanone and methylcyclohexanone; tertiary amine-based solvents such as picoline and pyridine; and ester-based solvents such as acetic acid (2-methoxy-1-methylethyl).

Specific examples of phenol-based solvents include phenol, o-cresol, m-cresol, p-cresol, 2,3-xylenol, 2,4-xylenol, 2,5-xylenol, 2,6-xylenol, 3,4-xylenol, and 3,5-xylenol.

Specific examples of ether-based solvents and glycol-based solvents include 1,2-dimethoxyethane, bis(2-methoxyethyl)ether, 1,2-bis(2-methoxyethoxy)ethane, bis[2-(2-methoxyethoxy)ethyl]ether, tetrahydrofuran, and 1,4-dioxane.

The organic solvent preferably has a boiling point at ordinary pressure of from 60° C. to 300° C., more preferably from 140° C. to 280° C., and still more preferably from 170° C. to 270° C. When the boiling point of the solvent is 300° C. or less, the organic solvent can be easily volatilized and removed in the step of forming the resin layer. When the boiling point of the solvent is 60° C. or more, a resin layer with a uniform surface state can be obtained.

In a case in which the composition B contains an organic solvent, the content thereof is not particularly limited, and may be, for example, from 1.0% by mass to 99.99896% by mass, or from 40% by mass to 99.99896% by mass with respect to the composition B as a whole.

### (Other Components)

The composition B may contain components other than those described above, if necessary.

For example, in a case in which selectivity of plasma etching resistance is required for the composition B (e.g., a case in which the composition B is used as a gap fill material or a buried insulating film), the composition B may contain a metal alkoxide represented by the following Formula (I):

R1ₙM(OR2)ₘ₋ₙ (I)

(where R1 is a non-hydrolyzable group, R2 is an alkyl group having from 1 to 6 carbon atoms. M represents at least one metal atom selected from the group consisting of Ti, Al, Zr, Sr, Ba, Zn, B, Ga, Y, Ge, Pb, P. Sb, V, Ta, W. La, Nd, and In, m is the valence of the metal atom M, which is 3 or 4, n is an integer from 0 to 2 when m is 4, and is 0 or 1 when m is 3, and when there are a plurality of R1's, R1's may be the same or different from one another, and when there are a plurality of OR2's, OR2's may be the same or different from one another).

In a case in which a film produced from the composition B is required to have insulating properties (e.g., for use as an insulating film for a through-silicon via or as a buried insulating film), the composition A may contain a silane compound (other than any one corresponding to the silane coupling agent (A)) in order to improve the insulating properties or mechanical strength.

Specific examples of the silane compound include tetraethoxysilane, tetramethoxysilane, bistriethoxysilylethane, bistriethoxysilylmethane, bis(methyldiethoxysilyl)ethane, 1,1,3,3,5,5-hexaethoxy-1,3,5-trisilacyclohexane, 1,3,5,7-tetramethyl-1,3,5,7-tetrahydroxylcyclosiloxane, 1,1,4,4-tetramethyl-1,4-diethoxydisilethylene, and 1,3,5-trimethyl-1,3,5-trimethyl-1,3,5-triethoxy-1,3,5-trisilacyclohexane.

The composition B may contain benzotriazole or a derivative thereof, for example, so as to inhibit copper corrosion.

The pH of the composition B is not particularly limited, but is preferably from 2.0 to 12.0.

The composition B preferably has a sodium and potassium content of 10 ppb by mass or less on an elemental basis. As long as the content of sodium or potassium is 10 ppb by mass or less on an elemental basis, the occurrence of problems in the electrical characteristics of the semiconductor device, such as malfunction of a transistor, can be suppressed.

In the composition B, the content of an inorganic or resin filler having a maximum diameter of 0.3 μm or more is preferably 30% by mass or less, more preferably 10% by mass or less, and still more preferably 0% by mass of the total nonvolatile content.

When the content of the filler contained in the composition B is within the above-described range, poor bonding of the laminated body can be suppressed even in a case in which the thickness of the resin layer formed using the composition B is reduced. In addition, when a first substrate having a resin layer formed thereon is layered onto a second substrate, the alignment marks formed on the substrates may be mechanically recognized and aligned. As long as the filler content is within the above-described range, the transparency of the resin film is improved, allowing more accurate alignment.

The disclosure of Japanese Patent Application No. 2023-015651, filed on Feb. 3, 2023, is incorporated herein by reference in its entirety.

All publications, patent applications, and standards mentioned herein are incorporated herein by reference to the same extent as if each individual publication, patent application, or standard was specifically and individually indicated to be incorporated by reference.

1. A semiconductor structure, comprising:
an organic bonding layer that comprises an organic insulating layer and a metal pad;
a plurality of silicon dies that are arranged in a two-dimensional manner on the organic bonding layer and hybrid-bonded to the organic bonding layer; and
a resin mold layer that is filled between the plurality of silicon dies on the organic bonding layer.

2. The semiconductor structure according to claim 1, further comprising at least one selected from the group consisting of a redistribution layer and a build-up substrate, the redistribution layer and the build-up substrate being arranged at a side opposite to a side at which the plurality of silicon dies are arranged, as viewed from the organic bonding layer.

3. (canceled)

4. The semiconductor structure according to claim 1, further comprising:
a high-density wiring layer that is arranged at a side opposite to a side at which the plurality of silicon dies are arranged, as viewed from the organic bonding layer, and
a build-up substrate that is arranged at a side opposite to a side at which the organic bonding layer is arranged, as viewed from the high-density wiring layer.

5. The semiconductor structure according to claim 1,
wherein the organic insulating layer comprises a cured product of the following composition A or a cured product of the following composition B,
wherein the composition A is a composition comprising:
a compound (A) having an Si—O bond and a cationic functional group comprising at least one selected from a primary nitrogen atom or a secondary nitrogen atom;
a compound (B) having three or more —C(═O)OX groups, wherein X is a hydrogen atom or an alkyl group having from 1 to 6 carbon atoms, and among the three or more —C(═O)OX groups, one to six are —C(═O)OH groups; and
a compound (C) having a ring structure and one or more primary nitrogen atoms directly bonded to the ring structure,
the composition A having a ratio of the primary nitrogen atom and secondary nitrogen atom contained in the compound (A) to a total of the primary nitrogen atom and secondary nitrogen atom contained in the compound (A) and the primary nitrogen atoms contained in the compound (C) of from 3% by mole to 95% by mole, and
wherein the composition B is
a composition comprising at least one of a compound (X1) having a structure represented by the following Formula (1) and a molecular weight of from 400 to 5,000 or a compound (X2) having a structure represented by the following Formula (2) and a molecular weight of from 400 to 5,000: 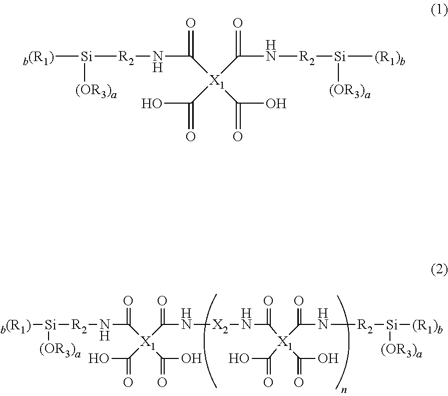
wherein, in Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride; and
wherein, in Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.

6. The semiconductor structure according to claim 1, wherein:
each of the plurality of silicon dies comprises a silicon die body and a silicon die bonding layer that is in contact with the organic bonding layer, and
the silicon die bonding layer comprises a metal pad and any one of an organic insulating layer, an SiO₂ layer, an SiCN layer or an SiN layer.

7. The semiconductor structure according to claim 1, wherein the resin mold layer covers upper surfaces of the plurality of silicon dies.

8. The semiconductor structure according to claim 1, further comprising a second organic bonding layer that comprises an organic insulating layer and a metal pad, and that is arranged at a side opposite to a side at which the organic bonding layer is arranged as viewed from the plurality of silicon dies.

9. The semiconductor structure according to claim 8, further comprising a plurality of second silicon dies that are arranged in a two-dimensional manner on the second organic bonding layer and hybrid-bonded to the second organic bonding layer.

10. The semiconductor structure according to claim 9, wherein:
each of the plurality of second silicon dies comprises a silicon die body and a silicon die bonding layer that is in contact with the second organic bonding layer, and
the silicon die bonding layer comprises a metal pad and any one of an organic insulating layer, an SiO₂ layer, an SiCN layer or an SiN layer.

11. The semiconductor structure according to claim 8, further comprising a second redistribution layer that is arranged between the second organic bonding layer and the plurality of silicon dies.

12. The semiconductor structure according to claim 8, further comprising a temporary fixing substrate or build-up substrate, which is arranged at a side opposite to a side at which the plurality of silicon dies are arranged as viewed from the organic bonding layer.

13. A method of manufacturing a semiconductor structure, comprising:
(A)
forming a redistribution layer on a temporary fixing substrate;
forming an organic bonding layer, which comprises an organic insulating layer and a metal pad, on the redistribution layer that is temporarily fixed on the temporary fixing substrate;
arranging a plurality of silicon dies in a two-dimensional manner on the organic bonding layer formed on the redistribution layer and hybrid-bonding the silicon dies to the organic bonding layer;
forming a resin mold layer that is filled between the plurality of silicon dies on the organic bonding layer and that covers upper surfaces of the plurality of silicon dies; and
removing the temporary fixing substrate; or
(B)
forming an organic bonding layer, which comprises an organic insulating layer and a metal pad, on a temporary fixing substrate;
arranging a plurality of silicon dies in a two-dimensional manner on the organic bonding layer formed on the temporary fixing substrate and hybrid-bonding the silicon dies to the organic bonding layer;
forming a resin mold layer that is filled between the plurality of silicon dies on the organic bonding layer and that covers upper surfaces of the plurality of silicon dies; and
removing the temporary fixing substrate; or
(C)
forming a high-density wiring layer on a build-up substrate;
forming an organic bonding layer, which comprises an organic insulating layer and a metal pad, on the high-density wiring layer;
arranging a plurality of silicon dies in a two-dimensional manner on the organic bonding layer formed on the high-density wiring layer and hybrid-bonding the silicon dies to the organic bonding layer; and
forming a resin mold layer that is filled between the plurality of silicon dies on the organic bonding layer and that covers upper surfaces of the plurality of silicon dies.

14. The method of manufacturing a semiconductor structure according to claim 13 wherein:
(A) further comprises:
forming an electrode at a side at which the temporary fixing substrate of the redistribution layer is removed; and
bonding the redistribution layer and a build-up substrate via the electrode.

15. (canceled)

16. The method of manufacturing a semiconductor structure according to claim 13, wherein:
(B) further comprises:
forming an electrode at a side at which the temporary fixing substrate of the organic bonding layer is removed; and
bonding the organic bonding layer and a build-up substrate via the electrode.

17. (canceled)

18. The method of manufacturing a semiconductor structure according to claim 13, wherein:
(C) further comprises:
removing a portion of the resin mold layer that covers the upper surfaces of the plurality of silicon dies so as to expose the upper surfaces of the plurality of silicon dies; and
forming a second organic bonding layer, which comprises an organic insulating layer and a metal pad, on the plurality of silicon dies having the upper surfaces exposed and the resin mold layer.

19. The method of manufacturing a semiconductor structure according to claim 18, wherein (C) further comprises arranging a plurality of second silicon dies in a two-dimensional manner on the second organic bonding layer and hybrid-bonding the second silicon dies to the second organic bonding layer.

20. The method of manufacturing a semiconductor structure according to claim 13, wherein (A) to (C) further comprise:
removing a portion of the resin mold layer that covers the upper surfaces of the plurality of silicon dies so as to expose the upper surfaces of the plurality of silicon dies; and
forming a second redistribution layer on the plurality of silicon dies having the upper surfaces exposed and the resin mold layer; and
forming a second organic bonding layer, which comprises an organic insulating layer and a metal pad, on the second redistribution layer.

21. The method of manufacturing a semiconductor structure according to claim 20, wherein (C) further comprises arranging a plurality of second silicon dies in a two-dimensional manner on the second organic bonding layer and hybrid-bonding the second silicon dies to the second organic bonding layer.

22. The method of manufacturing a semiconductor structure according to claim 13,
wherein the forming the organic bonding layer in (A) to (C) comprises curing the following composition A or the following composition B so as to form the organic insulating layer,
wherein the composition A is a composition comprising:
a compound (A) having an Si—O bond and a cationic functional group comprising at least one selected from a primary nitrogen atom or a secondary nitrogen atom;
a compound (B) having three or more —C(═O)OX groups, wherein X is a hydrogen atom or an alkyl group having from 1 to 6 carbon atoms, and among the three or more —C(═O)OX groups, one to six are —C(═O)OH groups; and
a compound (C) having a ring structure and one or more primary nitrogen atoms directly bonded to the ring structure,
the composition A having a ratio of the primary nitrogen atom and secondary nitrogen atom contained in the compound (A) to a total of the primary nitrogen atom and secondary nitrogen atom contained in the compound (A) and the primary nitrogen atoms contained in the compound (C) of from 3% by mole to 95% by mole, and
wherein the composition B is
a composition comprising at least one of a compound (X1) having a structure represented by the following Formula (1) and a molecular weight of from 400 to 5,000 or a compound (X2) having a structure represented by the following Formula (2) and a molecular weight of from 400 to 5,000: 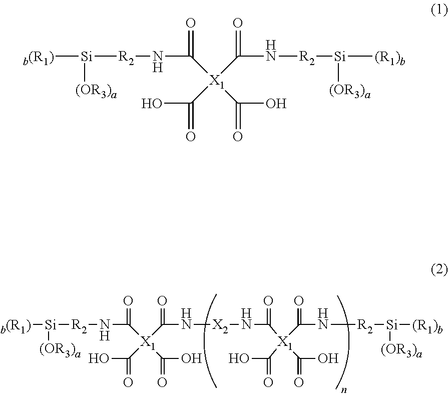
wherein, in Formula (1), R₁ and R₃ are each independently an organic group having 6 or fewer carbon atoms, R₂ is a methylene group, an ethylene group, a propylene group, or a phenylene group, a is 2 or 3, b is a number of 3-a, and X₁ is a structure derived from a carboxylic acid dianhydride; and
wherein, in Formula (2), R₁ and R₃ are each independently an organic group having 6 or fewer carbon atoms, R₂ is a methylene group, an ethylene group, a propylene group, or a phenylene group, a is 2 or 3, b is a number of 3-a, X₁ is a structure derived from a carboxylic acid dianhydride, X₂ is a structure derived from an amine compound, and n is a positive number.
